(19) United States
(12) Patent Application Publication
(10) Pub. No.: US 2024/0313775 A1
(43) Pub. Date: Sep. 19, 2024

(54) HIGH-TEMPERATURE SUPERCONDUCTING SWITCHES AND RECTIFIERS

(71) Applicant: VICTORIA LINK LIMITED, Wellington (NZ)

(72) Inventors: Rodney Alan Badcock, Wellington (NZ); Christopher William Bumby, Wellington (NZ); Jianzhao Geng, Hubei (CN); James Hamilton Palmer Rice, Wellington (NZ)

(21) Appl. No.: 18/272,975

(22) PCT Filed: Jan. 26, 2022
(86) PCT No.: PCT/NZ2022/050009

§ 371 Date: Jul. 18, 2023

(30) Foreign Application Priority Data
Jan. 26, 2021 (AU) 2021900162
Oct. 26, 2021 (AU) 2021903414

(51) Int. Cl. H03K 17/92; H01F 7/06

(52) U.S. Cl. CPC H03K 17/92; H01F 7/064

(57) ABSTRACT

There is provided a rectifier of an alternating input current, which may comprise: an electrical switch comprising a length of HITS material to carry an alternating switch current, the HITS material having a critical current: a magnetic field generator to apply a magnetic field to the HTS material: a control mechanism to control the magnetic field generator to switch the switch between a low-resistance state when a magnitude of the magnetic field is relatively low and a higher-resistance state when a magnitude of the magnetic field is relatively high, the relatively high magnitude being sufficient to reduce the critical current so that, for a part of the alternating switch current cycle, the current approaches the critical current, is substantially equal to the critical current or is greater than the critical current. There is further provided an electrical switch having two strands of superconducting material arranged in a bifilar arrangement.

### 1. FIELD OF INVENTION

The present technology relates to superconducting electrical switches and rectifiers. The present technology may particularly relate to electrical switches and rectifiers comprising components formed from superconducting materials, especially high-temperature superconducting materials.

### 2. BACKGROUND TO THE INVENTION

Superconducting circuits have a wide range of applications. Examples of applications for systems including superconducting circuits include (and are not limited to): superconducting magnets; flux pumps; fault current limiters; magnetic energy storage systems; space propulsion; nuclear fusion; nuclear magnetic resonance (NMR); magnetic resonance imaging (MRI); levitation; water purification and induction heating.

Many applications of superconducting circuits require, or benefit from, rectifying a current, i.e. converting an alternating current (AC, a current which periodically reverses in direction) to a direct current (DC, a current which flows only in one direction).

Rectifiers for superconducting circuits are known, but there is a need to provide improvements in superconducting rectifiers, and/or parts of rectifiers such as switches, to reduce losses, provide higher efficiencies compared to existing rectifiers and/or provide other benefits.

High-temperature superconductors (HTSs) have many applications including those listed above. Advancements in the manufacturing process for HTS coated conductors (CCs) have led to the development of wires which can carry a high current density at high magnetic fields. Coils wound from these CCs have shown superior performance as high field magnets/inserts. CC coils also show promise in many other applications, such as motors/generators, DC induction heaters and magnetic separators.

Although high current HTS coils are desirable and not difficult to manufacture, energising them typically requires large and complex electronic current supplies, and thick current leads which must physically transition between the room temperature and cryogenic temperature environments. This requires sophisticated thermal design and imposes a considerable heat penalty on the cryostat and cooling system. It also incurs a significant voltage drop across the normal conducting circuit components, necessitating a significantly higher-power supply than required solely to energise the superconducting coil.

One approach to eliminate the detrimental metal current leads from magnet systems is by wirelessly injecting a DC current into a closed-circuit HTS coil. This can be achieved through rectification of an AC current induced in the HTS secondary windings of a current transformer. Such ‘induced DC currents’, can be achieved using a type of device known as an HTS flux pump, and enable future HTS magnet systems which are much more compact and flexible.

Existing HTS flux pumps use periodic activation of high frequency electromagnetic switches. However these switches require separate independent power supplies and feedthroughs, which increase complexity. Also the switches are located within the cryostat, such that heat is dissipated in the cold environment, which adversely affects efficiency.

Flux pumps using low-temperature superconductors (LTSs) are known, including rectifier flux pumps. However, HTSs may not be appropriate for use in systems designed for LTSs as there are significant differences between HTSs and LTSs. For example, LTS materials typically have a low critical magnetic field (of magnitude <1 T), but HTSs have upper critical fields of magnitudes of several tens of Tesla. Some existing flux pumps rely on transitioning out of the superconducting state through the application of temperature or magnetic field. It is not practically feasible in most applications to apply the strength of magnetic field, or apply a fast enough thermal pulse, that would be necessary to transition a HTS out of the superconducting state.

There is therefore a particular need to provide improvements in rectifiers, including rectifiers suitable for use with HTSs (for example, in flux pumps), and/or parts of rectifiers such as switches, to reduce losses, provide higher efficiencies compared to existing rectifiers and/or provide other benefits.

### 3. OBJECT OF THE INVENTION

It is an object of the technology to meet any one or more of the aforementioned advantages/needs by providing an electrical switch comprising at least one component formed of a superconducting material and/or by providing a rectifier comprising an electrical switch comprising at least one component formed of a superconducting material. Alternatively, it is an object of the technology to at least provide the public with a useful choice.

### 4. SUMMARY OF THE INVENTION

According to one aspect of the technology there is provided an electrical switch comprising a length of superconducting material. In some forms the electrical switch is configured to be controlled between a low-resistance superconducting state and a higher-resistance superconducting state by the selective application of a magnetic field to the length of superconducting material so that, in the higher-resistance state, current flowing through the length of superconducting material approaches the critical current of the length of superconducting material, is substantially equal to the critical current or is greater than the critical current. In some forms, the length of superconducting material is a length of high temperature superconducting material.

According to another aspect of the technology there is provided a rectifier configured to rectify an alternating input current. The rectifier may comprise an electrical switch comprising a length of high temperature superconducting (HTS) material configured to carry an alternating switch current, wherein the length of HTS material has a critical current. The rectifier may further comprise a magnetic field generator configured and arranged to apply a magnetic field to the HTS material. The rectifier may further comprise a control mechanism to control the magnetic field generator to switch the electrical switch between a low-resistance state when a magnitude of the magnetic field is relatively low and a higher-resistance state when a magnitude of the magnetic field is relatively high, the relatively high magnitude being sufficient to reduce the critical current of the length of HTS material so that, for a part of a cycle of the alternating switch current, the alternating switch current approaches the critical current, is substantially equal to the critical current or is greater than the critical current. The electrical switch may be arranged to rectify the alternating input current to produce a direct current output.

In examples:
a) the electrical switch may be arranged to half-wave rectify the alternating input current, wherein the direct current output is delivered to a load connected in parallel across the electrical switch;
b) the control mechanism may be configured to control the magnetic field generator such that the magnitude of the magnetic field is based on a phase of the alternating input current;
c) the control mechanism may supply an alternating generator current to the magnetic field generator such that the magnitude of the magnetic field varies in phase with a phase of the alternating switch current;
d) the rectifier may comprises a current control mechanism to control the alternating switch current such that a first peak current of the alternating switch current when the alternating switch current flows in a first direction approaches, is substantially equal to, or is greater than the critical current of the length of the HTS material when the magnitude of the magnetic field applied by the magnetic field generator is relatively high, and a second peak current when the alternating switch current flows in a second direction is less than the critical current of the length of the HTS material when the magnitude of the magnetic field applied by the magnetic field generator is relatively high, the second direction being opposite the first direction;
e) the magnetic field generator may comprise a magnetic core forming a gap, and the magnetic field generator may comprise a conductor wound around a part of the magnetic core in a coil, the conductor carrying the alternating generator current, wherein the length of HTS material is positioned in the gap;
f) the alternating input current may be supplied directly to the conductor as the alternating generator current, and wherein the alternating switch current is based on the alternating input current;
g) the rectifier may comprise a transformer, the transformer comprising a primary side and secondary side, wherein the primary side receives the alternating input current and the secondary side is connected to the electrical switch;
h) the conductor may be connected to the primary side of the transformer;
i) the conductor may be connected to the secondary side of the transformer;
j) the transformer may comprise the magnetic core forming the gap;
k) the control mechanism may comprise a current flow control device configured to control the alternating generator current through the magnetic field generator;
l) the current flow control device may comprise a diode connected in parallel across the magnetic field generator such that the magnetic field generator is activated when the alternating generator current flows in a first direction and the magnetic field generator is de-activated when the alternating generator current flows in a second direction, the second direction being opposite to the first direction;
m) the current flow control device may comprise a generator control switch connected in parallel across the magnetic field generator such that the magnetic field generator is activated when the generator control switch is open and the magnetic field generator is de-activated when the generator control switch is closed, wherein the control mechanism comprises a controller configured to control the opening and closing of the generator control switch;
n) the rectifier may further comprise at least one further electrical switch comprising a further length of high temperature superconducting (HTS) material configured to carry a further alternating switch current, wherein the length of HTS material has a critical current;
o) the rectifier may further comprise, for each of the at least one further electrical switch, a further magnetic field generator configured and arranged to apply a further magnetic field to the further length of HTS material;
p) the control mechanism may be configured to control the further magnetic field generator to switch the respective further electrical switch between a low-resistance state when a magnitude of the further magnetic field is relatively low and a higher-resistance state when a magnitude of the further magnetic field is relatively high, the relatively high magnitude being sufficient to reduce the critical current of the further length of HTS material so that, for a part of a cycle of the alternating switch current, the alternating switch current approaches the critical current, is substantially equal to the critical current or is greater than the critical current;
q) the at least one further electrical switch may be arranged to operate with the electrical switch to rectify the alternating input current to produce the direct current output;
r) the control mechanism may be configured to activate and de-activate each of the respective magnetic field generators to switch the respective electrical switches between the low-resistance state when the respective magnetic field generator is de-activated and the higher-resistance state when the respective magnetic field generator is activated;
s) the further magnetic field generators may comprise a second magnetic field generator, wherein the control mechanism may be configured such that the magnetic field generator is activated when the second magnetic field generator is de-activated and the magnetic field generator is de-activated when the second magnetic field generator is activated;
t) the at least one further electrical switch may comprise a second electrical switch, and wherein the electrical switch and the second electrical switch may be connected in series and the direct current output is delivered to a load connected in parallel across one of the switches;
u) the at least one further electrical switch may comprise a second electrical switch, and wherein the electrical switch and the second electrical switch may be arranged to full-wave rectify the alternating input current;
v) the electrical switch and the second electrical switch may be connected in series and the direct current output is delivered to a load connected in parallel between the two electrical switches;
w) the at least one further electrical switch may comprise second, third and fourth electrical switches, wherein a first pair of electrical switches may comprise the electrical switch connected in series to the second electrical switch, and a second pair of electrical switches may comprise the third electrical switch connected in series to the fourth electrical switch, the first pair of electrical switches being connected in parallel to the second pair of electrical switches, and wherein the direct current output may be delivered to a load connected between a first terminal and a second terminal, wherein the first terminal may be between the electrical switch and the second electrical switch and the second terminal is between the third electrical switch and the fourth electrical switch;
x) the magnetic core may comprise a first core part and a second core part, wherein the first core part and second core part are separated by a thermal break;
y) the transformer may comprise a magnetic core comprising a first core part and a second core part, wherein the primary side may comprise the first core and the secondary side may comprise the second core part, wherein the first core part and second core part may be separated by a thermal break;
z) the first core part may be located outside a cryostat and the second core part may be located inside the cryostat;
aa) the magnetic field generator may comprise a thermal break between the magnetic core and the conductor;
bb) the transformer may comprise a magnetic core and a thermal break between the magnetic core and one or more conductors forming the primary side and/or the secondary side; and
cc) the thermal break may comprise thermally insulating material.

According to another aspect of the technology, there is provided an electrical switch comprising a length of superconducting material configured to carry a transport current and having a critical current. The electrical switch may further comprise a magnetic field generator configured and arranged to apply a magnetic field to the length of superconducting material. The length of superconducting material may be arranged in a bifilar arrangement. The magnetic field generator may comprise a high permeability magnetic core. The magnetic field generator may be configured to be selectively controlled to switch the electrical switch between a low-resistance state when a magnitude of the magnetic field is relatively low and a higher-resistance state when a magnitude of the magnetic field is relatively high. In the low-resistance state the transport current may be substantially less than the critical current. In the higher-resistance state the transport current may approach the critical current, be substantially equal to the critical current or be greater than the critical current.

According to another aspect of the technology, there is provided an electrical switch comprising first and second strands of superconducting material, each of the first and second strands of superconducting material being configured to carry a transport current and having a critical current. The electrical switch may further comprise a magnetic field generator configured and arranged to apply a magnetic field to the first and second strands of superconducting material. The magnetic field generator may comprise a high permeability magnetic core. The magnetic field generator may be configured to be selectively controlled to switch the electrical switch between a low-resistance state when a magnitude of the magnetic field is relatively low and a higher-resistance state when a magnitude of the magnetic field is relatively high. In the low-resistance state the transport current may be substantially less than the critical current. In the higher-resistance state the transport current may approach the critical current, be substantially equal to the critical current or be greater than the critical current. The first and second strands of superconducting material may be spatially arranged substantially parallel to each other within a region of the magnetic field and are electrically connected so that the transport current flows in opposite directions through the first and second strands of superconducting material within the region of the magnetic field.

In examples:
a) The high permeability magnetic core may comprise a first end and a second end separated by a gap, the first and second strands of superconducting material being positioned in the gap;
b) The first and second strands of superconducting material may be in the form of tapes each having two opposed faces;
c) The tapes may be arranged so that the opposed faces of the first strand of superconducting material are parallel with the opposed faces of the second strand of superconducting material;
d) The tapes may be oriented such that the magnetic field applied to the first and second strands of superconducting material is substantially perpendicular to each of the two opposed faces;
e) The electrical switch may comprise a length of superconducting material comprising the first and second strands of superconducting material; or the first and second strands of superconducting material may be electrically connected by connecting a face of the first strand to a face of the second strand; and
f) The superconducting material is high temperature superconducting (HTS) material.

According to another aspect of the technology, there is provided an electrical switch comprising a length of superconducting material configured to carry a transport current and having a critical current. The electrical switch may further comprise a magnetic field generator configured and arranged to apply a magnetic field to the length of superconducting material. The magnetic field generator may comprise a high permeability magnetic core. The magnetic field generator may be configured to be selectively controlled to switch the electrical switch between a low-resistance state when a magnitude of the magnetic field is relatively low and a higher-resistance state when a magnitude of the magnetic field is relatively high. In the low-resistance state the transport current may be substantially less than the critical current. In the higher-resistance state the transport current may approach the critical current, be substantially equal to the critical current or be greater than the critical current. The length of superconducting material may be arranged to substantially cancel a self-magnetic field generated by the transport current flowing through the length of superconducting material when in proximity to the high permeability magnetic core.

According to another aspect of the technology, there is provided a rectifier according to any one aspect of the technology, wherein the electrical switch is the electrical switch according to any one aspect of the technology. In another aspect of the invention, there is provided the use of an electrical switch according to any one aspect of the technology in a rectifier according to any one aspect of the technology.

Further aspects of the technology, which should be considered in all its novel aspects, will become apparent to those skilled in the art upon reading of the following description which provides at least one example of a practical application of the technology.

### 5. BRIEF DESCRIPTION OF THE DRAWINGS

One or more embodiments of the technology will be described below by way of example only, and without intending to be limiting, with reference to the following drawings, in which:

FIG. 1 shows an exemplary electric-field versus current graph for a high-temperature superconductor;

FIG. 2 is an illustration of graphs of electric field against current for a superconducting material when three external magnetic fields of different magnitude are applied;

FIG. 3 is a schematic illustration of a rectifier according to one form of the technology;

FIG. 4 is a perspective view illustration of the rectifier shown in FIG. 3;

FIG. 4A is an illustration of three graphs illustrating parameters relating to the form of rectifier shown in FIGS. 3 and 4;

FIG. 5 is a schematic illustration of a rectifier according to another form of the technology;

FIG. 6 is a perspective view illustration of the rectifier shown in FIG. 5;

FIG. 7 is an illustration showing the magnitudes of parameters varying with time during use of the rectifier shown in FIGS. 5 and 6;

FIG. 8 is a schematic illustration of a rectifier according to another form of the technology;

FIG. 9 is a perspective view illustration of the rectifier shown in FIG. 8;

FIG. 10 is a schematic illustration of a rectifier according to another form of the technology;

FIG. 11 is a perspective view illustration of the rectifier shown in FIG. 10;

FIG. 12 is a schematic illustration of a rectifier according to another form of the technology;

FIG. 13 is a schematic illustration of a rectifier according to another form of the technology;

FIG. 14 is a schematic illustration of a rectifier according to another form of the technology;

FIG. 15 is an illustration showing the magnitudes of parameters varying with time during use of the rectifier shown in FIG. 14;

FIG. 16 is a schematic illustration of a rectifier according to another form of the technology;

FIG. 17 is a schematic illustration of a rectifier according to another form of the technology;

FIG. 18 is an illustration showing the magnitudes of parameters varying with time during use of the rectifier shown in FIG. 17;

FIG. 19 is a schematic illustration of a rectifier according to another form of the technology;

FIG. 20 is a schematic illustration of a rectifier according to another form of the technology;

FIG. 21 is a schematic illustration of a rectifier according to another form of the technology;

FIG. 22 is a schematic illustration of a rectifier according to another form of the technology;

FIG. 23 is a schematic illustration of a rectifier according to another form of the technology;

FIG. 24 is a perspective view illustration of the rectifier shown in FIG. 23;

FIG. 25 is an illustration showing the measured magnitudes of parameters varying with time during use of the rectifier shown in FIGS. 23 and 24;

FIG. 26 is a schematic illustration of a rectifier according to another form of the technology;

FIG. 27 is a perspective view illustration of the rectifier shown in FIG. 26;

FIG. 28 is an illustration showing the magnitudes of parameters varying with time during use of the rectifier shown in FIGS. 26 and 27;

FIG. 29 is a schematic illustration of a rectifier according to another form of the technology;

FIG. 30 is a perspective view illustration of the rectifier shown in FIG. 29;

FIG. 31 is an illustration showing the magnitudes of parameters varying with time during use of the rectifier shown in FIGS. 29 and 30;

FIG. 32 is a schematic illustration of a transformer according to one form of the technology;

FIG. 33 is a schematic illustration of a transformer according to another form of the technology;

FIG. 34 is a perspective view illustration of a rectifier according to another form of the technology;

FIG. 35 is a perspective view illustration of a rectifier according to another form of the technology;

FIG. 36A is a schematic illustration of an electrical switch according to one form of the technology;

FIG. 36B is a schematic illustration of an electrical switch according to another form of the technology;

FIG. 37 is a graph illustrating the relationship between critical current of a length of superconducting material in an electrical switch according to a form of the technology at different applied fields and when the length of superconducting material is arranged in a bifilar arrangement and a unifilar arrangement;

FIG. 38A shows a magnetic field profile for an electrical switch according to one form of the technology; and

FIG. 38B shows a magnetic field profile for an electrical switch according to another form of the technology.

### 6. DETAILED DESCRIPTION OF EXAMPLES OF THE TECHNOLOGY

### 6.1. Discussion on Superconductors

To aid in the understanding of the present technology the reader should be familiar with superconducting terminology including the critical temperature for a superconductor and the critical current for a superconductor. Nevertheless, for the benefit of the reader we briefly discuss these concepts below.

The critical temperature for a superconductor is conventionally defined as the temperature, below which the resistivity of the superconductor drops to zero or near zero. In other words, a superconductor is said to be in its superconducting state when the temperature of the superconductor is below the critical temperature and in a non-superconducting state when the temperature is above the critical temperature. Many superconductors have a critical temperature which is near absolute zero; for example, mercury is known to have a critical temperature of 4.1K. It is however also known that some materials can have critical temperatures which are much higher such as 30K to 125K; for example, magnesium diboride has a critical temperature of approximately 39K, while yttrium barium copper oxide (YBCO) has a critical temperature of approximately 92K. These superconductors are often generally referred to as high-temperature superconductors.

The critical current for a high-temperature superconductor wire or tape is conventionally defined as the current flowing in a superconductor wire/tape which results in an electric field drop along the wire of 100 μV/m (=1 μV/cm). It should be appreciated that the critical current is a function of both the superconducting material used, and the physical arrangement of the superconducting material. For example, a wider tape/wire may have a higher critical current than a thinner tape/wire constructed of the same material. Nevertheless, it should be understood that, throughout the specification, reference to the critical current of the superconductor/superconducting material is made to simplify the discussion.

In a superconductor/superconducting material, if the current I is approximately equal to the critical current I_{c}, the resistance of the superconductor is non-zero, but small. However, if I is much larger than the critical current I_{c}, the resistance of the superconductor becomes sufficiently large to cause heat dissipation which can heat the superconductor to a temperature above its critical temperature, which in turn causes it to no longer be superconducting. This condition is sometimes referred to as a “quench” and can be damaging to the superconductor itself.

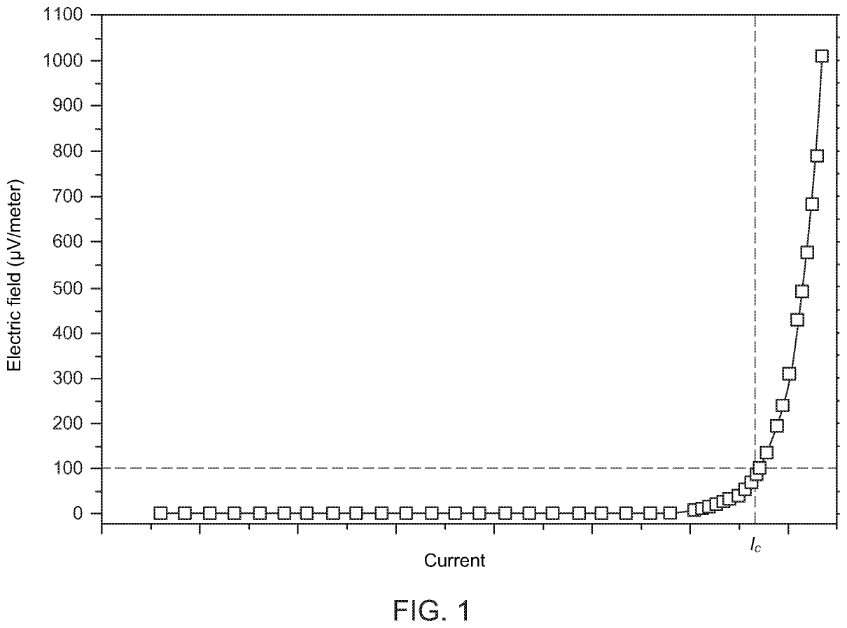

FIG. 1 shows an exemplary plot depicting the internal electric-field versus current curve for a high-temperature superconductor. It should be appreciated that the electric-field shown in this plot is related to resistance via the following equation:

$$E = \frac{IR}{L}$$

### Where:

E is the electric field;
I is the current through the superconductor;
R is the resistance of the wire; and
L is the length of the wire.

Accordingly, the plot of FIG. 1 is related to the resistance per-unit length for the superconductor and, because the curve depicted is non-linear, the resulting resistance for the superconductor is non-linear with current.

In this figure it can be seen that the electric field strength in the superconductor is substantially zero below the critical current I_{c} for the superconductor. As the current in the superconductor approaches the critical current, the electric-field in the superconductor starts to increase. At the critical current, the electric-field in the superconductor is 100 μV/m. Further increasing the current in the superconductor above the critical current results in rapid increases in the electric-field strength in the conductor.

Throughout the present specification reference will be made to the relative resistances of a superconducting material and components comprising a superconducting material. More particularly, the specification refers to a superconducting material being in a low-resistance or higher-resistance state. It will be appreciated that, when in a superconducting state, superconducting materials can have a resistance which is zero or substantially zero, and as such these resistances are often expressed in terms of the electric field present across the superconducting material for a given current. Nevertheless, throughout the present specification, reference is made to relative resistances, for example low-resistance and higher-resistance states of the superconducting material, in order to simplify the foregoing discussion.

The term ‘low-resistance state’ may refer to when the superconducting material has a resistance that is close to or substantially zero in the superconducting state, or when the material has a low resistance in a partially superconducting state. The term ‘higher-resistance’ state refers to a state in which the superconducting material has a resistance that is substantially greater than the resistance in the low resistance state, for example a substantially non-zero resistance or a resistance that is close to zero but substantially greater than the resistance in the low-resistance state. For the avoidance of doubt, a higher-resistance state as referred to in this specification may, unless the context clearly indicates otherwise, include a superconducting state.

Similarly, where in this specification, reference is made to a superconductor being in a higher-resistance state as a result of a current carried by the superconductor exceeding the critical current, it should be understood that, unless the context clearly indicates otherwise, the higher-resistance state may also be achieved if the current carried by the superconductor approaches or is substantially equal to the critical current.

In describing the technology in this specification, material and components comprising the material are referred to as “superconducting”. This term is commonly used in the art for such materials and should not be taken to mean that the relevant material is always in a superconducting state. Under certain conditions the material and components comprising the material may not be in a superconducting state. That is, the material may be described as being superconductive but not superconducting.

### 6.2. Superconducting Materials

Certain forms of the present technology may comprise a variety of types of superconducting material.

For example, forms of the technology may comprise high-temperature superconducting (HTS) materials. Exemplary HTS materials suitable for use in the forms of technology described include copper-oxide superconductors, for example a rare-earth barium copper oxide (ReBCO) such as yttrium barium copper oxide, gadolinium barium copper oxide or bismuth strontium calcium copper oxide (BSCCO) superconductors, and iron-based superconductors. BSCCO superconductors typically have a strong interdependence between critical current and an applied magnetic field, which may make them particularly suitable for some forms of the present technology. Other types of superconductors may be used in other forms of the technology.

While forms of the technology will be described in relation to high-temperature superconductors, it should be understood that other forms of the technology may use other types of superconductor, for example low-temperature superconductors, in their place.

In certain forms, the superconducting material may be provided in the form of a tape.

### 6.3. Effect of Magnetic Field on Superconductors

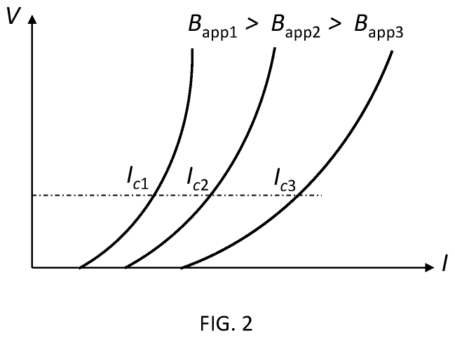

The critical current in a superconductor is dependent on the external magnetic field applied to the superconductor. More particularly, the critical current decreases as a higher external magnetic field is applied to the superconductor, up to the value of the critical field, above which the superconductor is no longer in the superconducting (low resistance) state. This relationship is shown in FIG. 2, which is an illustration of graphs of electric field against current for a superconducting material when three external magnetic fields of different magnitude are applied. The highest magnitude of external magnetic field, Bₐₚₚ₁, results in the lowest critical current, I_{c1}.

### 6.4. Electrical Switch

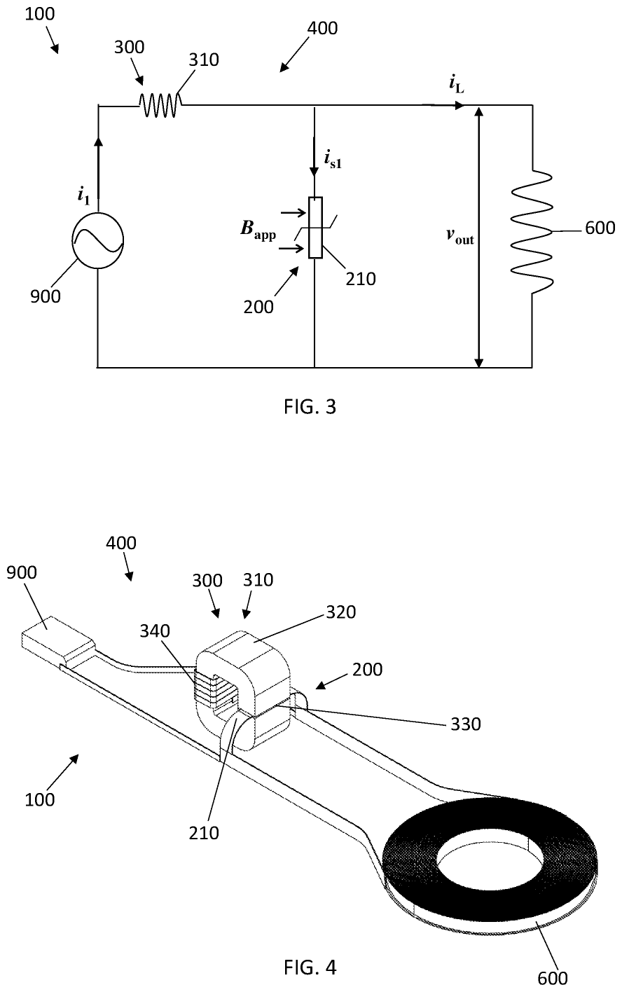

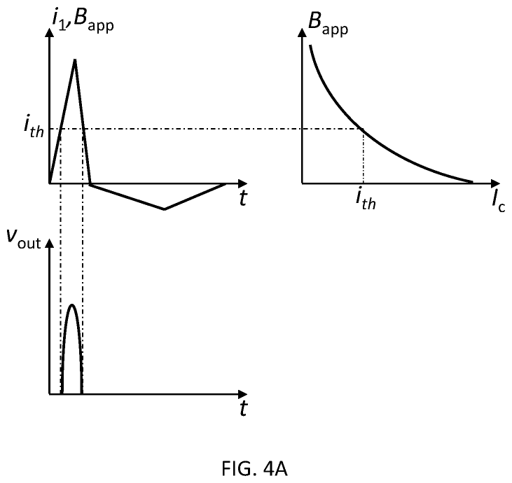

Forms of the technology relate to an electrical switch that utilise the principle that the critical current of a superconducting material decreases as a higher external magnetic field is applied to the material. An exemplary electrical switch 210 is illustrated in FIGS. 3 and 4. The form of the technology illustrated in these figures will be described in more detail below, but for present purposes the switch 210 is described.

Electrical switch 210 comprises a length of high temperature superconducting (HTS) material, for example any of the types of HTS material described above. The HTS material has a critical current I_{c} and a critical temperature T_{c}. The HTS material is positioned inside a cryostat 710 (not shown) configured to maintain the HTS material at a temperature that is less than the critical temperature T_{c}.

When an external magnetic field Bₐₚₚ is applied to the length of HTS material the critical current reduces, as shown in FIG. 2. The application of the magnetic field Bₐₚₚ can therefore be used to cause the length of HTS material to act as a switch. If the HTS material carries a switch current (i.e. a current flowing through the electrical switch 210) that is less than the critical current when the magnitude of the magnetic field Bₐₚₚ has a certain value then the HTS material will be in a low-resistance state. If the magnitude of the magnetic field Bₐₚₚ is increased from that value to a relatively high magnitude that is sufficiently high that the critical current reduces to a value that is closer to, or below, the magnitude of the current carried by the HTS material, then the HTS material will be in a higher-resistance state.

The low-resistance state of the HTS material can be considered equivalent to the closed state of switch 210 while the higher-resistance state is similar to an open state of switch 210. It should be appreciated, however, that the higher-resistance state is not an electrical open-circuit as would be common for a mechanical switch, but rather represents a higher-resistance conductive state. In this higher-resistance conductive state, the HTS material may remain in the superconducting state but with a higher level of resistance, or it may be in a non-superconducting state.

The difference in magnitude of the magnetic field Bₐₚₚ between the low-resistance state and higher-resistance state of the switch may be varied to a plurality of magnitudes, including a continuously variable magnitude and including varying it between two magnitudes. In the low-resistance state the magnitude of the magnetic field Bₐₚₚ may be zero or non-zero.

It will be appreciated that any magnitude of the magnetic field Bₐₚₚ applied to the HTS material should be below the magnitude of the critical field, where the critical field is the magnitude of the external magnetic field applied to the HTS material that causes the HTS material to move into the higher-resistance state.

The energy loss in a superconducting switch is nearly proportional to the critical current in the switch during switching. Since the electrical switch 210 operates by reducing the value of the critical current during switching, the electrical switch 210 (and devices comprising the electrical switch 210 have lower losses and therefore higher efficiencies than conventional superconducting switches.

### 6.5. Rectifier

Certain forms of the technology use electrical switch 210, and in certain forms multiple electrical switches 210 in the form of a switching assembly 200, to rectify an alternating input current. Different forms of the technology may utilise one or more electrical switches 210 in any configuration in order to produce a rectifying effect. In the following description, examples of suitable configurations of electrical switches are described, although it should be understood that other configurations may be used in other forms of the technology.

Rectifiers 100 according to forms of the technology comprise the following functional parts: a switching assembly 200; a magnetic field generator assembly 300; a control mechanism 400; and a current supply assembly 500. These functional parts will be described in more detail below, with descriptions of exemplary forms of each functional part. Some specific examples of rectifiers 100 comprising combinations of exemplary forms of each functional part will also be described. It should be understood that other combinations of exemplary forms of each functional part are also provided in some forms of the technology, and the technology is not limited to the specific examples illustrated and/or described.

In certain forms, the current supply assembly 500 is configured to supply alternating current to the switching assembly 200. The switching assembly 200 comprises an arrangement of one or more electrical switches 210 and is configured to rectify the alternating current to produce a direct current output. The direct current output may be delivered to load 600. The magnetic field generator assembly 300 comprises one or more magnetic field generators 310, each configured to apply a magnetic field to one or more of the electrical switches 210. The control mechanism 400 controls the magnetic field generator assembly 300 in order to switch the electrical switches 210 of the switching assembly 200.

Any part of the rectifier 100 comprising superconducting materials is housed in one or more cryostats 710 configured to maintain the superconducting material at a temperature that is less than the critical temperature T_{c} of the respective superconducting material.

### 6.6. Switching Assemblies

In certain forms of the technology, the switching assembly 200 comprises an arrangement of one or more electrical switches 210 and is configured to rectify the alternating current to produce a direct current output. The arrangement of the electrical switches 210 in the switching assembly 200 determines the type of rectification performed by rectifier 100, as will be described below through examples.

In certain forms of the technology, the rectifier 100 is a half-wave rectifier. A half-wave rectifier allows current flowing in one direction to pass but blocks current flowing in the other direction. In some forms of a half-wave rectifier, the switching assembly comprises a single electrical switch 210. In other forms of a half-wave rectifier, the switching assembly comprises two electrical switches 210.

Exemplary forms of switching assemblies 200 for a half-wave rectifier 100 comprising a single switch 210 are illustrated in FIGS. 3, 4, 5, 6, 8, 9, 10, 11, 12, 13 and 19. In these forms a load 600 is connected in parallel across the electrical switch 210. When the switch 210 is in the ‘closed’ configuration, there is no voltage across the load 600 and a load current i_{L} is delivered to the load 600. When the switch 210 is in the ‘open’ configuration, a voltage Vₒᵤₜ is developed across the load 600 and a load current it is delivered to the load 600. Whether the load current it increases or decreases when the switch 210 is opened depends on the direction of the switch current iₛ₁ flowing through the switch 210, which depends on the timing of the opening of the switch 210 compared to the phase of the alternating input current i₁. In some forms, the control mechanism 400 may control the opening and closing of the switch 210 so that the switch 210 is open when the alternating input current i₁ flows in one direction and the switch 210 is closed when the alternating input current i₁ flows in the opposite direction, i.e. the control mechanism 400 controls the state of each of the switches 210 in a timed manner based on a phase of the alternating input current i₁. In this way, the voltage Vₒᵤₜ may be only developed across the load 600 in one direction (or polarity), thereby providing a half-wave rectifier. In other forms the control mechanism 400 may control the opening and closing of the switch 210 to occur at different times in the current cycle. The control mechanism 400 may be used to open and close switch 210 at selected times in the phase of the alternating input current i₁ so that the voltage Vₒᵤₜ across the load 600 causes the load current i, to change in a desired way, including increasing and decreasing the load current i_{L} at different times. Changing the load current it in the load 600 in a step-like fashion in this way may be described as “pumping”.

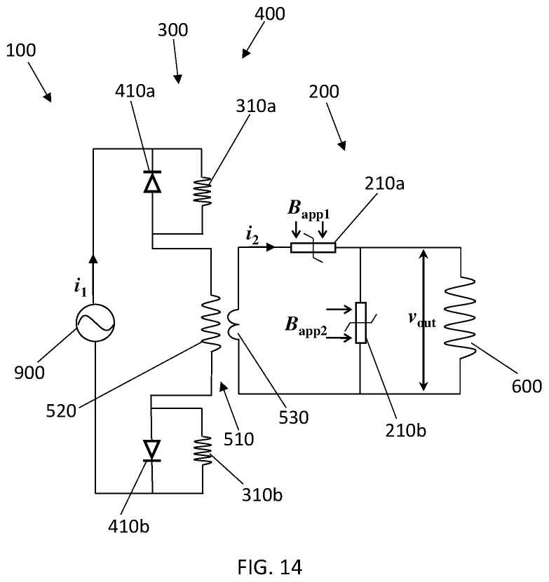

Exemplary forms of switching assemblies 200 for a half-wave rectifier 100 comprising two switches 210a, 210b are illustrated in FIGS. 14, 20 and 23. In these forms the two switches 210a, 210b are connected in series and a load 600 is connected in parallel across one of the switches 210. An alternating current i₂ is provided to the switching assembly 200. The switching assembly 200 is controlled by a control mechanism 400 configured to control the state of each of the switches 210 in order to rectify the alternating current i₂. For example, the control mechanism 400 controls each of the switches 210 so that the state of each switch is based on the direction of flow of the alternating current i₂. Since the direction of flow of the alternating current i₂ depends on the phase of the current, in this form the control mechanism 400 controls the state of each of the switches 210 in a timed manner based on a phase of the alternating current i₂. For example, when the alternating current i₂ is flowing in a first direction (i.e. the current flow is positive) the first switch 210a is placed in its low-resistance state and the second switch 210b is placed in its higher-resistance state. As such, a low resistance path is formed around the outside of the loop through switch 210a and across the load 600. As the polarity of the current changes (for example from positive to negative), the control mechanism 400 may cause switch 210a to transition into its high-resistance state, and switch 210b to transition to a low-resistance state. The higher-resistance state of 210a impedes the current flow from the transformer, providing a measure of blocking to the negative polarity current flow. Simultaneously, the low-resistance state of 210b provides a path for the current flow in the load to continue, albeit while exponentially decaying with a time constant L/R (which will mean that the load current will remain constant if the load is superconducting). Accordingly, the current flow through the load 600 may be half-wave rectified. Again, the control mechanism 400 may open and close switches 210a and 210b at appropriate times to increase and decrease the current in the load 600 as desired.

In some forms of the technology, the control mechanism 400 may control both switch 210a and switch 210b to be simultaneously in the low-resistance state for some period of time in the alternating current cycle. That is to say that switch 210b may be in a higher-resistance state for only a portion of the time that i₂ is positive, and switch 210a may be in a higher-resistance state for only a portion of the time that i₂ is negative and, for the rest of time, both switches are in a low-resistance state whether i₂ is positive or negative. This may be used as a practical control strategy to ensure that a switch is in the open configuration (i.e. the higher-resistance state) when the current through it is in the desired direction. The control mechanism 400 may control the switches of the rectifiers of any of the forms of technology described herein in this way, even if not expressly stated.

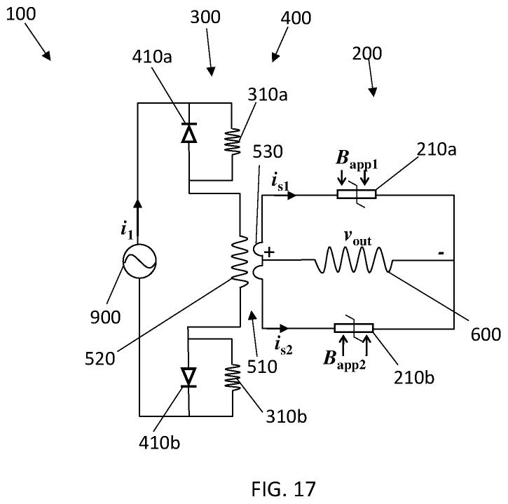

Exemplary forms of switching assemblies 200 for a full-wave rectifier 100 comprising two switches 210a, 210b are illustrated in FIGS. 17, 22 and 26. Two switches 210a, 210b are connected in series and a load 600 is connected in parallel between the two switches 210a, 210b. An alternating current is provided to the switching assembly 200. The switching assembly 200 is controlled by a control mechanism 400 configured to control the state of each of the switches 210 in order to rectify the alternating current. For example, the control mechanism 400 may control each of the switches 210 so that the state of each switch is based on the direction of flow of the alternating current. Since the direction of flow of the alternating current depends on the phase of the current, in this form the control mechanism 400 controls the state of each of the switches 210 in a timed manner based on a phase of the alternating current. When the current is flowing in a first direction (for example when the current is positive) the first switch 210a is placed into its low-resistance state, while the second switch 210b is placed into its higher-resistance state. This results in a lower impedance path around the top half of the circuit through switch 210a, and results in a current flow through the load 600 in a first direction. When the alternating is flowing in a second direction (for example when the current is negative) the first switch 210a is placed into is higher-resistance state, while the second switch 210b is placed into a low-resistance state. This results in a lower impedance path around the bottom half of the circuit through switch 210b, and results in a current flow through the load 600 in the first direction. When the opening and closing of the switches is controlled in this way, irrespective of the direction of the alternating current, the current always flows through the load in a single direction, e.g. from the positive terminal to the negative terminal. Accordingly, the voltage Vₒᵤₜ may be only developed across the load 600 in one direction (or polarity) and the alternating current is full-wave rectified into a direct current through the load 600. As with the earlier example of the half-wave rectifier, the control mechanism 400 may control the timing of the opening and closing of the switches 210 so that the voltage across the load is developed with the desired polarity and the current through the load 600 increases or decreases accordingly.

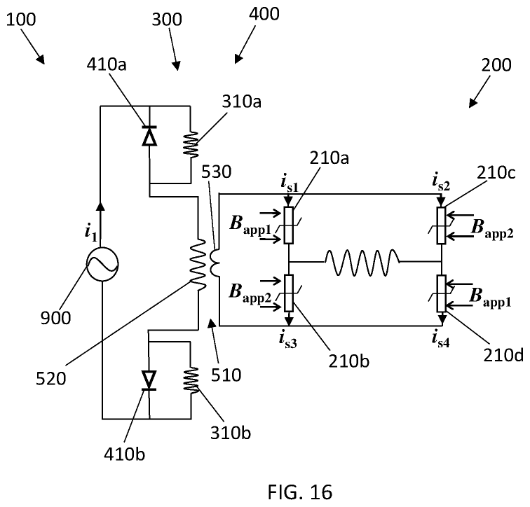

Exemplary forms of switching assemblies 200 for a full-wave rectifier 100 comprising four switches 210a, 210b, 210c and 210d are illustrated in FIGS. 16, 21, 29 and 30. Two switches 210a and 210b form a first pair of switches and are connected in series to each other. The other two switches 210c and 210d form a second pair of switches and are connected in series to each other. The two pairs of switches are connected in parallel to each other, each in parallel with a source of alternating current. Load 600 is connected from a terminal between the switches 210a, 210b of the first pair of switches to a terminal between the switches 210c, 210d of the second pair of switches. The switching assembly 200 is controlled by a control mechanism 400 configured to control the state of each of the switches 210 in order to rectify the alternating current. For example, the control mechanism 400 may control each of the switches 210 so that the state of each switch is based on the direction of flow of the alternating current. Since the direction of flow of the alternating current depends on the phase of the current, in this form the control mechanism 400 controls the state of each of the switches 210 in a timed manner based on a phase of the alternating current. When the current is flowing in a first direction (for example when the current is positive) the first and fourth switches 210a, 210d are placed into their low-resistance state, while the second and third switches 210b, 210c are placed into their higher-resistance state. This results in a lower impedance path through the first and fourth switches 210a and 210d, and results in a current flow through the load 600 in a first direction. When the alternating is flowing in a second direction (for example when the current is negative) the first and fourth switches 210a, 210d are placed into their higher-resistance state, while the second and third switches 210b, 210c are placed into third low-resistance state. This results in a lower impedance path through the second and third switches 210b and 210c, and results in a current flow through the load 600 in the first direction. When the opening and closing of the switches is controlled in this way, irrespective of the direction of the alternating current, the current always flows through the load in a single direction, e.g. from the positive terminal to the negative terminal. Accordingly, the voltage Vₒᵤₜ may be only developed across the load 600 in one direction (or polarity) and the alternating current is full-wave rectified into a direct current through the load 600. As with the earlier example of the half-wave rectifier, the control mechanism 400 may control the timing of the opening and closing of the switches 210 so that the voltage across the load is developed with the desired polarity and the current through the load 600 increases or decreases accordingly.

While certain exemplary arrangements of switches 210 in a switching assembly 200 have been described, it should be understood that other switching assemblies 200 in other forms of the technology have other arrangements of switches 210 for rectifying an alternating current. Switching assemblies 200 of other forms of the technology may have other numbers of switches 210.

### 6.7. Magnetic Field Generator Assembly

In certain forms of the technology, the magnetic field generator assembly 300 comprises one or more magnetic field generators 310, each of the magnetic field generators 310 being configured to apply a magnetic field to one or more of the electrical switches 210 of the switching assembly 200.

Exemplary forms of magnetic field generator assemblies 300 are illustrated in FIGS. 3-6, 8-14, 16, 17, 19-24, 26, 27, 29, 30, 34 and 35. In these forms, the magnetic generator assembly 300 comprises one or more magnetic field generators 310. Each of the magnetic field generators 310 may comprise a magnetic core 320. The core 320 may be a high-permeability magnetic core such as a ferrite core (e.g. an iron core) or a laminated steel/iron cores. In other forms, other types of high relative permeability at the operating frequency may also be used, or a non-magnetic core or air core may be used. Air cores may advantageously reduce the size, weight and cost of the electrical switch 210 and may also provide the ability to drive higher currents without saturating the core. In the illustrated forms the magnetic core 320 is a substantially ring-shaped solid core, for example a square-shaped ring having rounded corners.

In the exemplary forms, the magnetic core 320 forms a gap 330. The gap 330 may be a space in a solid magnetic core 320, for example a space in one side of a square-shaped ring core. Any part of an air core may be considered to be a gap 330.

In the exemplary forms, a conductor is wound around a part of the magnetic core 320 in a coil 340. For example, the coil 340 formed by the conductor may be wound around a side of a square-shaped ring core, for example the side opposite the side on which the gap 330 is formed. In an air core, the coil 340 defines inside it a region of space, and that region of space may be considered to be the air core and to contain the gap 330. In use, the conductor may carry a generator current. The flow of the generator current through the coil 340 generates a magnetic field, including in core 320 and across gap 330. In certain forms of the technology, the length of HTS material comprising an electrical switch 210 is positioned in the gap 330 such that the magnetic field generated by the magnetic field generator 310 across gap 330 is an external magnetic field Bₐₚₚ applied to the switch 210.

In certain forms, the generator current carried by the conductor may be supplied by a current source, for example an alternating current source so that that generator current is an alternating generator current. As will be described in more detail later, in certain forms, the alternating current source supplying current to the conductor may be the same alternating input current received by the current supply assembly 500 of the rectifier 100, or an alternating current supply with a magnitude varying in phase with the alternating input current and/or with an alternating switch current flowing through the switch 210 positioned in the gap 330. In other forms, the current source supplying generator current to the conductor of the magnetic field generator 310 may be a separate current source 350. In these forms, the current source 350 may be a direct current source.

The magnitude of the magnetic field generated by the magnetic field generator(s) 310 may be continuously varying. Alternatively, the magnitude of the magnetic field generated by the magnetic field generator(s) 310 may vary between two constant values. In certain forms, one of the constant values may be zero.

In certain forms, a magnetic field generator 310 may be configured to apply a magnetic field Bₐₚₚ to a plurality of electrical switches 210. For example, in the form of rectifiers 100 shown in FIGS. 16, 21, 29 and 30, magnetic field generator 310a is configured to apply a magnetic field to electrical switches 210a and 210d and magnetic field generator 310b is configured to apply a magnetic field to electrical switches 210b and 210c. Each magnetic field generator 310a and 310b may comprise a single magnetic core 320 and one or more gaps 330, within which the HTS material of the respective electrical switches are positioned. Alternatively, as in the example shown in FIG. 30, each magnetic field generator 310a and 310b may comprise a plurality of component magnetic field generators, each comprising a magnetic core 320 and having a conductor wound round them to form a coil 340, where the coils 340 of each component magnetic field generator are electrically connected in order to energise the component magnetic field generators simultaneously.

While certain exemplary arrangements of magnetic field generators 300 in a magnetic field generator assembly 300 have been described, it should be understood that other magnetic field generators 310 in other forms of the technology may take other forms.

### 6.8. Control Mechanism

Rectifiers 100 according to certain forms of the technology comprise a control mechanism 400 configured to control the magnetic field generator assembly 300 in order to switch the electrical switches 210 of the switching assembly 200.

In certain forms of the technology, the control mechanism 400 is configured to control the magnetic field generator(s) 310 of the magnetic field generator assembly 300 such that the magnitude of the magnetic field generated by each magnetic field generator 310 is based on a phase of the alternating input current received by the current supply assembly 500. For example, the magnitude of the magnetic field generated by each magnetic field generator 310 may vary with a phase that is a fixed phase difference from a phase of the alternating input current. In one example, the fixed phase difference may be zero, in which case the magnetic field generated by each magnetic field generator 310 varies in phase with the alternating input current. In certain examples, the magnitude of the magnetic field generated by each magnetic field generator 310 may be a first value for a part of each cycle of the alternating input current, and a second value for another part of each cycle of the alternating input current. One of the first or second values may be zero.

Additionally, in certain forms, the control mechanism 400 is configured to supply an alternating current to the magnetic field generator 310 (i.e. an alternating generator current) that has a phase based on a phase of an alternating current through the electrical switch 210 to which the magnetic field generator 310 supplies a magnetic field (i.e. an alternating switch current). Therefore, the magnitude of the magnetic field generated by the magnetic field generator 310 varies in phase with a magnitude of the alternating switch current. For example, the magnitude of the alternating generator current may vary with a phase that is a fixed phase difference from a phase of the alternating switch current. In one example, the fixed phase difference may be zero, in which case the magnetic field generated by each magnetic field generator 310 varies in phase with the alternating switch current. In certain examples, the magnitude of the magnetic field generated by each magnetic field generator 310 may be a first value for a part of each cycle of the alternating switch current, and a second value for another part of each cycle of the alternating switch current. One of the first or second values may be zero.

In certain forms of the technology, the alternating input current may be supplied directly to the magnetic field generator 310 as the alternating generator current. In examples in which the magnetic field generator 310 comprises a conductor wound in a coil 340, the alternating input current may be supplied directly to the conductor/coil 340.

In certain forms of the technology described above, the alternating input current, or an alternating current based on the alternating input current (including, for example: an alternating current split from the alternating input current at a current divider; or an alternating current generated in the secondary side of a transformer from the alternating input current in a primary side of the transformer), is supplied to a magnetic field generator 310 where: 1) the magnetic field generator 310 applies a magnetic field to the electrical switch 210; and 2) the electrical switch 210 carries an alternating switch current based on the alternating input current (again, including, for example: an alternating current split from the alternating input current at a current divider; or an alternating current generated in the secondary side of a transformer from the alternating input current in a primary side of the transformer). Such forms of the technology may be considered to comprise one or more “auto-synchronous” electrical switches 210 since the timing of the change in magnitude of the external magnetic field Bₐₚₚ applied to the electrical switches 210 is automatically synchronised to the phase of the alternating input current by the relationship between the currents. In these forms, the control mechanism 400 may be considered to be the electrical components and/or connections that facilitate the stated relationships between the alternating input current and the alternating generator and alternating switch currents.

In certain forms, a portion of the external magnetic field Bₐₚₚ applied to the electrical switches 210 may be automatically synchronised to the phase of the alternating input current in the manner described, and the magnetic field generator 310 may comprise a generator portion configured to generate another portion of the external magnetic field Bₐₚₚ by another means.

Certain examples of auto-synchronous electrical switches 210 provided in rectifiers 100 according to forms of the technology will now be described.

In the form of rectifier 100 illustrated in FIGS. 3 and 4, the magnetic field generator 310 receives a supply of alternating input current i₁ from an alternating current source 900. This magnetic field generator 310 is configured to generate a magnetic field Bₐₚₚ and to apply that magnetic field to electrical switch 210. As is shown in FIG. 4, the magnetic field generator comprises a coil 340 wound around magnetic core 320 where the coil 340 carries the alternating input current i₁. The coil 340 is electrically connected to a length of HTS material comprised as part of electrical switch 210 and positioned in a gap 330 in the magnetic core 320. Consequently changes in the alternating input current i₁ result in changes to the applied magnetic field Bₐₚₚ and the two are synchronised.

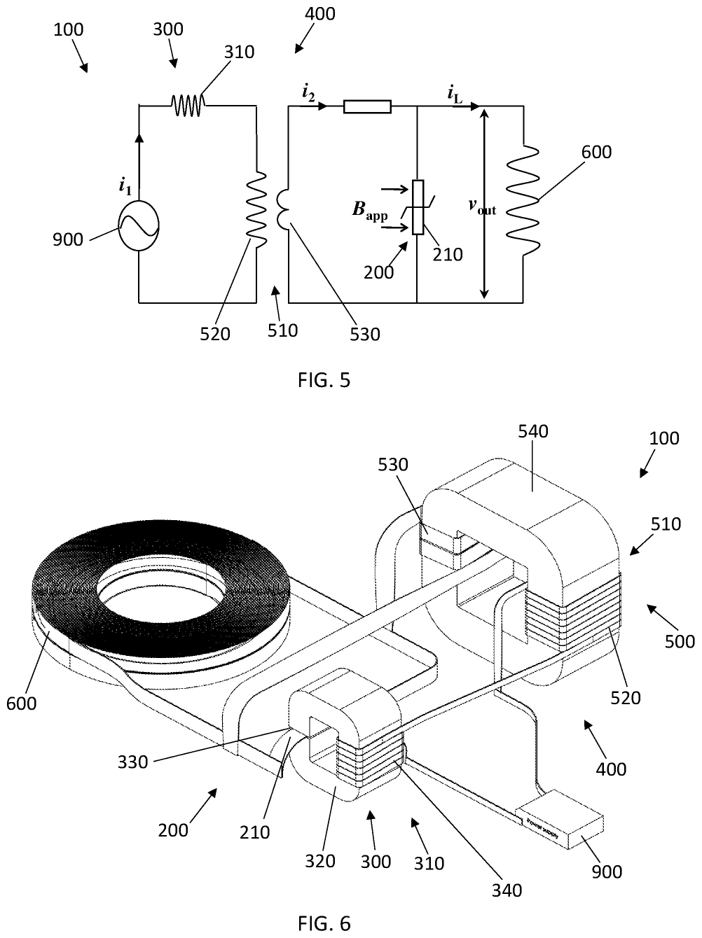

In the form of rectifier 100 illustrated in FIGS. 5, 6, 12 and 19, the alternating current source 900 supplies alternating input current i₁ to the magnetic field generator 310, which is configured to generate a magnetic field Bₐₚₚ and to apply that magnetic field to electrical switch 210. As is shown in FIG. 6, the magnetic field generator comprises a coil 340 wound around magnetic core 320 where the coil 340 carries the alternating input current i₁. The coil 340 is electrically connected to a primary coil 520 on the primary side of a transformer 510. The transformer 510 generates an alternating current i₂ in a secondary coil 530 on the secondary side of the transformer 510. The secondary coil 530 is electrically connected to a length of HTS material comprised as part of electrical switch 210 and positioned in a gap 330 in the magnetic core 320. Since the alternating current i₂ in the secondary coil 530 is synchronised with, i.e. in phase with, the alternating input current i₁ in the primary coil 520, changes in the alternating input current i₁ result in changes to the applied magnetic field Bₐₚₚ and the two are synchronised.

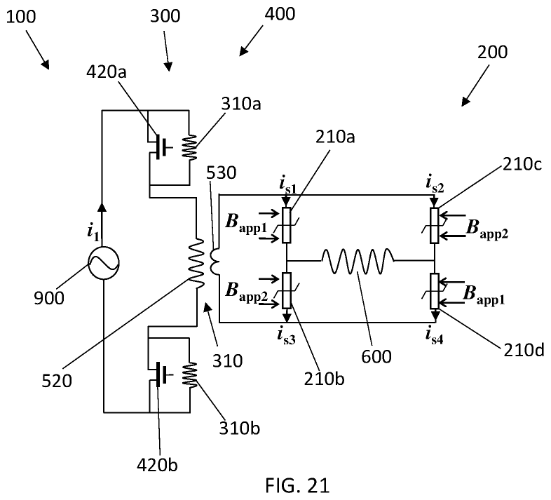

In the form of rectifier 100 illustrated in FIGS. 14, 16, 17, 20, 21 and 22, the magnetic field generator assembly 300 is on the primary side of the transformer 510, similarly to the forms shown in FIGS. 5, 6, 12 and 19. In the case of the forms shown in FIGS. 14, 16, 17, 20, 21 and 22, the magnetic field generator assembly 300 comprises a plurality of magnetic field generators 310, for example two magnetic field generators 310a and 310b, each configured to apply a magnetic field Bₐₚₚ₁ and Bₐₚₚ₂ respectively to electrical switches 210a and 210b (or respectively to electrical switches 210a and 210d, and 210b and 210c in the case of the forms shown in FIGS. 16 and 21).

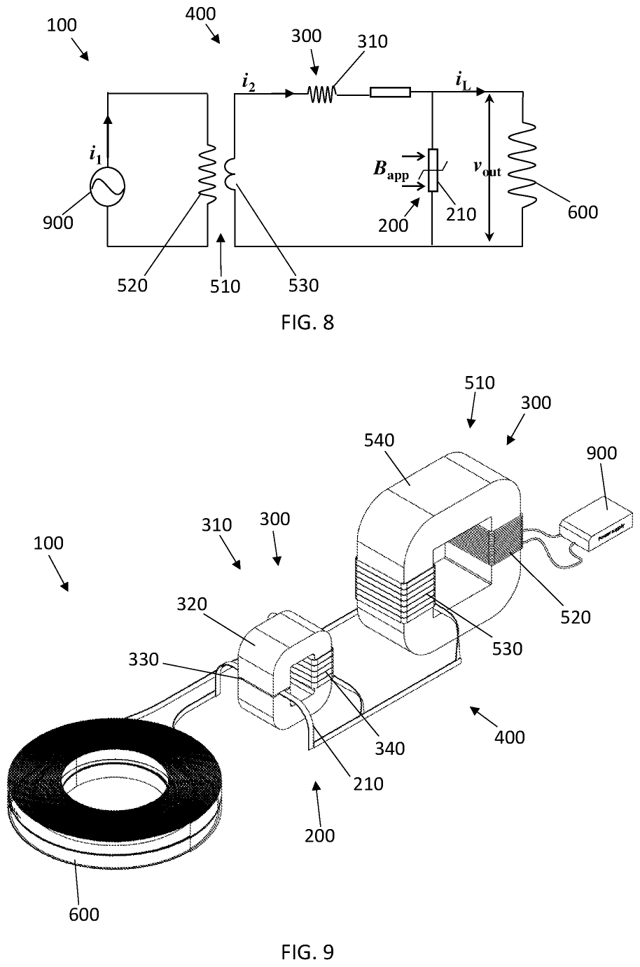

In the form of rectifier 100 illustrated in FIGS. 8, 9 and 13, the alternating current source 900 supplies alternating input current i₁ to a primary coil 520 on the primary side of a transformer 510. The transformer 510 generates an alternating current i₂ in a secondary coil 530 on the secondary side of the transformer 510. The secondary coil 530 is electrically connected to the magnetic field generator 310, which is configured to generate a magnetic field Bₐₚₚ and to apply that magnetic field to electrical switch 210. As is shown in FIG. 9, the magnetic field generator comprises a coil 340 wound around magnetic core 320 where the coil 340 carries the alternating current i₂ provided from the secondary coil 530. The coil 340 is electrically connected to a length of HTS material comprised as part of electrical switch 210 and positioned in a gap 330 in the magnetic core 320. Since the alternating current i₂ in the secondary coil 530 is synchronised with, i.e. in phase with, the alternating input current i₁ in the primary coil 520, changes in the alternating input current i₁ result in changes to the applied magnetic field Bₐₚₚ and the two are synchronised.

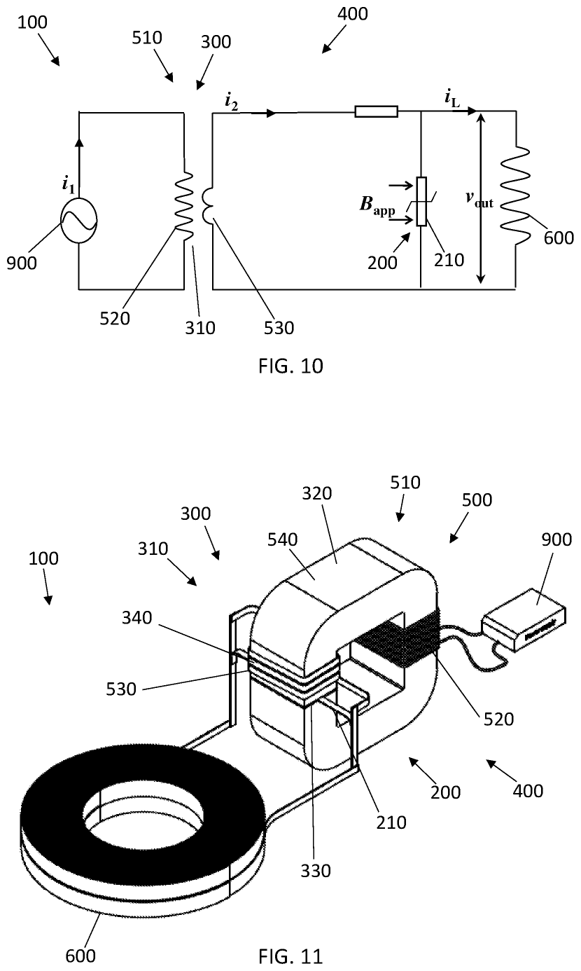

In the form of rectifier 100 illustrated in FIGS. 10 and 11, the alternating current source 900 supplies alternating input current i₁ to a primary coil 520 on the primary side of a transformer 510. The transformer 510 generates an alternating current i₂ in a secondary coil 530 on the secondary side of the transformer 510. In this form, the transformer 510 and magnetic field generator 310 are comprised of the same components, i.e. the magnetic core 320 of the magnetic field generator 310 also serves as the magnetic core 540 of the transformer 510. This magnetic core 320/540 comprises a gap 330 in which is positioned a length of HTS material comprised as part of electrical switch 210 and this length of HTS material is electrically connected to the secondary coil 530 of the transformer 510. Since the alternating current i₂ in the secondary coil 530 is synchronised with, i.e. in phase with, the alternating input current i₁ in the primary coil 520, changes in the alternating input current i₁ result in changes to the applied magnetic field Bₐₚₚ and the two are synchronised. The rectifier 100 in this form of the technology may be more compact than the rectifier shown in FIGS. 5, 6, 8 and 9 since only a single magnetic core 320/540 is used.

In some forms of the technology, the control mechanism 400 comprises one or more current flow control devices configured to control the alternating generator current through any one or more of the magnetic field generators 310.

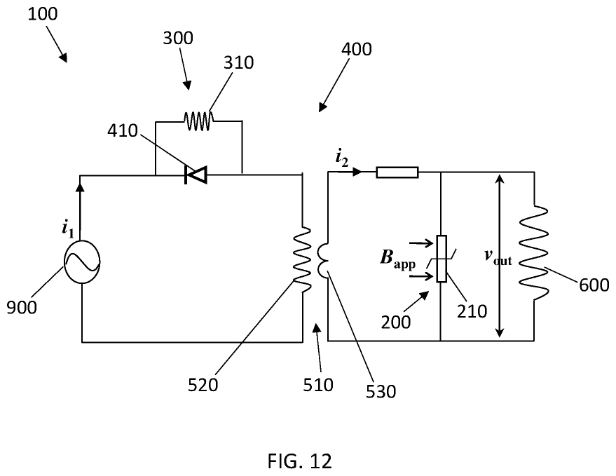

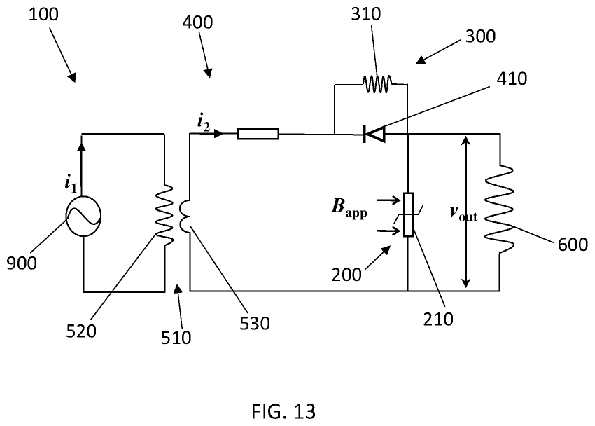

In certain forms of the technology each current flow control device comprises a diode 410 connected in parallel across one of the magnetic field generators 310. In certain forms, the diode 410 may be a type of diode configured to allow current to flow through the diode 410 in one direction but to block current flow through the diode 410 in the other, opposite, direction. Forms of rectifiers 100 including diodes of this type are illustrated in FIGS. 12, 13, 14, 16 and 17. In these forms, when the current flows in the direction through which the diode 410 allows current to flow, the magnetic field generator 310 is shorted and consequently de-activated. When the current flows in the direction through which the diode 410 blocks current, the current flows through the magnetic field generator 310, activating the magnetic field generator 310. This means that the electrical switch 210 that is controlled by the magnetic field Bₐₚₚ applied by the magnetic field generator 310, is only able to be activated (i.e. put into the higher-resistance state, or opened) during one half of the alternating current cycle. One advantage of the forms of rectifier 100 including a diode 410 over other types of rectifier 100 described herein is that, since a magnetic field generator 310 results in resistive losses of energy when current flows through the windings of coil 340, the diode 410 means that substantially no resistive losses occur during half of the cycle when the diode 410 allows current to flow and no current flows through the magnetic field generator 310.

In the forms of the technology shown in FIGS. 14, 16 and 17, the rectifier 100 comprises a plurality of current flow control devices which, in these forms, each comprises a diode so that the rectifier 100 comprises a plurality of diodes 410a, 410b. Each diode 410a and 410b is connected in parallel across a respective one of the magnetic field generators 310a and 310b. The diodes 410a and 410b are oriented in the opposite direction to each other so that, when the alternating input current i₁ flows in one direction, diode 410a allows current to flow and diode 410b blocks current flow, and, when the alternating input current i₁ flows in the other, opposite, direction, diode 410a blocks current flow and diode 410b allows current to flow. The result of this arrangement is that, when the alternating input current i₁ flows in one direction, magnetic field generator 310b is activated while magnetic field generator 310a is not, and, when the alternating input current i₁ flows in the other, opposite, direction, magnetic field generator 310a is activated while magnetic field generator 310b is not. This means that the electrical switches 310a and 310b (to which the magnetic field generators 310a and 310b apply magnetic fields respectively) are able to be switched when the alternating input current i₁ is flowing in both directions.

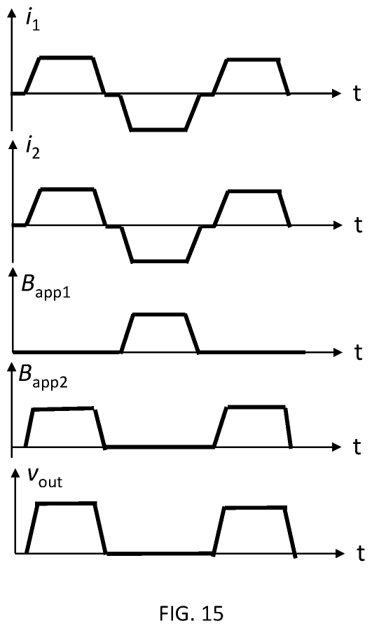

FIG. 15 illustrates exemplary magnitudes of the alternating input current i₁, secondary current i₂, magnetic field Bₐₚₚ₁ generated by magnetic field generator 310a, magnetic field Bₐₚₚ₂ generated by magnetic field generator 310b and output voltage across the load 600 varying with time during use of the exemplary half-wave rectifier 100 of FIG. 14 according to one form of the technology. The magnitude of the alternating input current i₁ may be controlled by the current supply assembly 500 (not shown) to have the illustrated wave-profile, which is reflected in the profile of the magnitude of the secondary current i₂. The diode 410a causes the magnetic field Bₐₚₚ₁ generated by magnetic field generator 310a to be activated for the positive part of the cycle of the alternating input current i₁ and otherwise to be de-activated. The diode 410b causes the magnetic field Bₐₚₚ₂ generated by magnetic field generator 310b to be activated for the positive part of the cycle of the secondary current i₂ and otherwise to be de-activated. The effect of the rectifier 100 is that a voltage is generated across the load 600 during only the positive parts of the cycle of the alternating input current i₁, thus half-wave rectifying the alternating input current i₁.

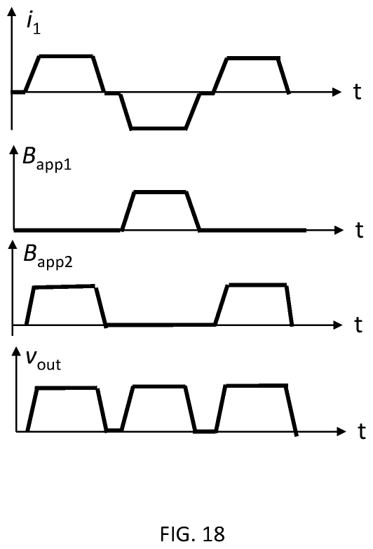

FIG. 18 illustrates exemplary magnitudes of the alternating input current i₁, magnetic field Bₐₚₚ₁ generated by magnetic field generator 310a, magnetic field Bₐₚₚ₂ generated by magnetic field generator 310b and output voltage across the load 600 varying with time during use of the exemplary full-wave rectifiers 100 of FIGS. 16 and 17 according to forms of the technology. The magnitude of the alternating input current i₁ may be controlled by the current supply assembly 500 to have the illustrated wave-profile. This profile is reflected in the magnitude of the secondary current in the secondary coil 530 (not shown). The diode 410a causes the magnetic field Bₐₚₚ₁ generated by magnetic field generator 310a to be activated for the positive part of the cycle of the alternating input current i₁ and otherwise to be de-activated. The diode 410b causes the magnetic field Bₐₚₚ₂ generated by magnetic field generator 310b to be activated for the positive part of the cycle of the secondary current i₂ and otherwise to be de-activated. The effect of the rectifier 100 is that a positive voltage is generated across the load 600 whenever the alternating input current i₁ is non-zero (whether negative or positive), thus full-wave rectifying the alternating input current i₁.

The forms of rectifier 100 illustrated in FIGS. 14, 16 and 17 comprise multiple diodes 410 and multiple electrical switches 210. These rectifiers may operate with only one current supply 900 and the control mechanism 400 is driven by the alternating input current i₁, i.e. no external control mechanism may be required. In some forms, they may be more efficient and to suffer lower cryogenic losses than the forms of rectifier 100 illustrated in FIGS. 5, 6, 8, 9, 10, 11, 12 and/or 13. Furthermore, the forms of rectifier 100 illustrated in FIGS. 14, 16 and 17 may operate with a symmetric alternating input current i₁ (i.e. it is not necessary to control the input current to have an asymmetric wave-profile, as may be required for the forms of rectifier 100 illustrated in FIGS. 5, 6, 8, 9, 10, 11, 12 and/or 13, as will be described below) and may therefore generate an output voltage across load 600 for a significant proportion of the cycle, therefore increasing the output voltage and power compared to those other forms of rectifier. In some forms, however, the rectifiers 100 of FIGS. 14, 16 and 17 may be physically larger than rectifiers 100 disclosed herein comprising only single electrical switches 210, and the timing of activation/de-activation of the switches 210 may not be as efficient as compared to forms of rectifier in which the control mechanism 400 controlling the timing of activation/de-activation of switches is a separate part of the rectifier (i.e. non-auto-synchronous forms).

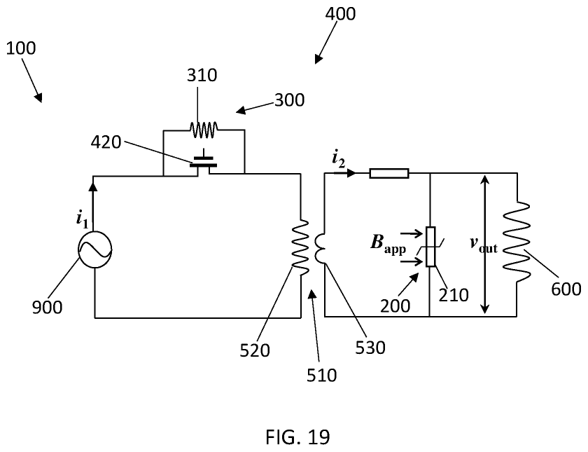

In certain forms of the technology, the control mechanism 400 comprises one or more current flow control devices in the form of a generator control switch 420 connected in parallel across the magnetic field generator 310. In certain forms, the generator control switch 420 may be a switch in the form of a transistor, for example a MOSFET or IGBT. Forms of rectifier 100 comprising generator control switches 420 are illustrated in FIGS. 19-22. In these forms, control mechanism 400 comprises a switch control mechanism (not shown) configured to selectively open and close the generator control switches 420 in order to activate/de-activate the magnetic field generator 310 connected in parallel with each generator control switch 420 by allowing current to pass therethrough, or shorting the magnetic field generator 310, respectively. While such a switch control mechanism introduces additional complexity to the rectifier 100 compared to the rectifiers in which the current flow control device comprises one or more diodes, the switch control mechanism allows active control of the electrical switches 210, which may provide more flexibility and may allow greater efficiencies to be achieved in some forms of the technology. Furthermore, only a single current supply 900 may be required.

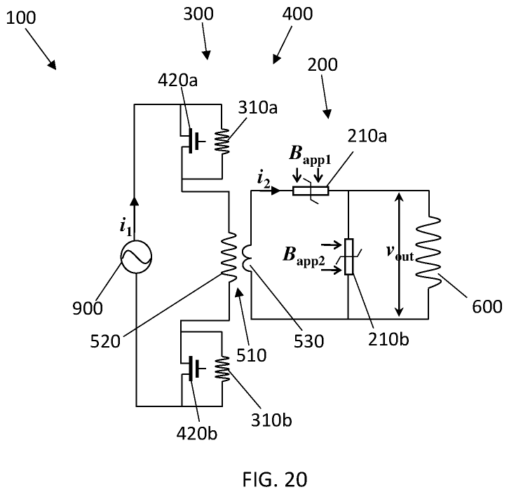

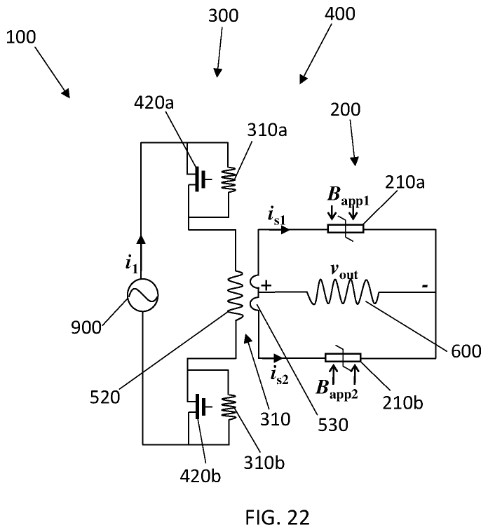

The exemplary rectifiers 100 shown in FIGS. 19 and 20 are half-wave rectifiers. The form of rectifier 100 in FIG. 19 comprises a single generator control switch 420 connected in parallel to the magnetic field generator 310. The control mechanism 400 is configured to selectively open and close switch 420 based on the phase of the alternating input current i₁ in order to half-wave rectify the current, in a similar manner to that described above. In the form of half-wave rectifier 100 shown in FIG. 20, and in the forms of exemplary full-wave rectifiers 100 shown in FIGS. 21 and 22, the control mechanism 400 comprises a first switch 420a connected in parallel across one magnetic field generator 310a and a second switch 420b connected in parallel across another magnetic field generator 310b. The control mechanism 400 is configured to selectively open and close switches 420a and 420b based on the phase of the alternating input current i₁ in order to rectify the current.

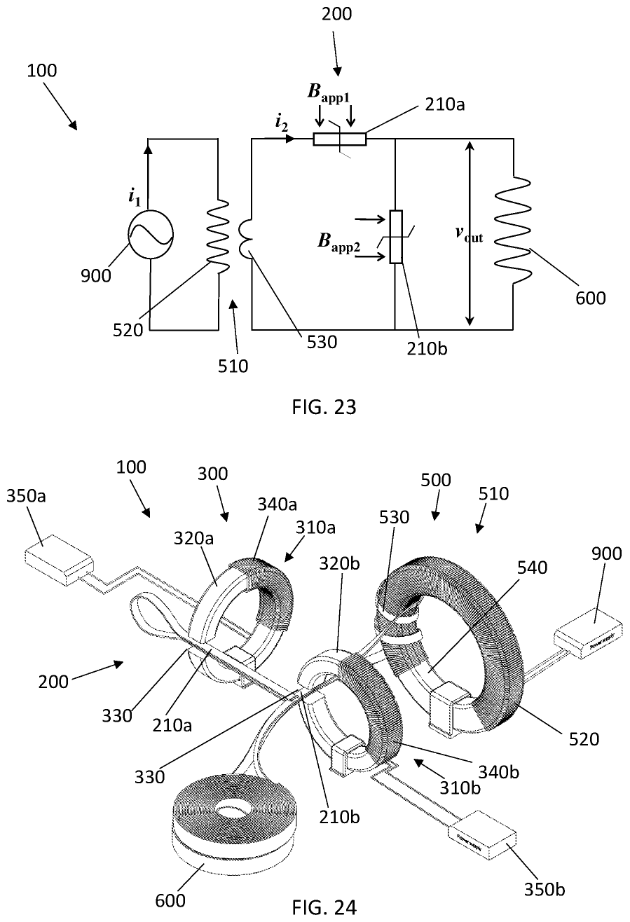

The exemplary forms of rectifier described above are forms in which the magnetic field generator assembly 300 is energised by the alternating input current or a current based on the alternating input current (including, for example: an alternating current split from the alternating input current at a current divider; or an alternating current generated in the secondary side of a transformer from the alternating input current in a primary side of the transformer). In other forms of the technology, the magnetic field generator assembly 300 comprises one or more separate current/power sources 350. Exemplary such forms of the technology are illustrated in FIGS. 23, 24, 26, 27, 29 and 30.

In the exemplary form of rectifier 100 shown in FIGS. 23 and 24, the magnetic fields Bₐₚₚ₁ and Bₐₚₚ₂ applied to electrical switches 210 are generated by magnetic field generators 310a and 310b respectively, and the coils 340a and 340b carry current supplied by current sources 350a and 350b respectively. Control mechanism 400 (not shown) is configured to control the supply of current from current sources 350a and 350b to the coils 340a and 340b to activate and de-activate the magnetic field generators 310a and 310b in a desired manner.

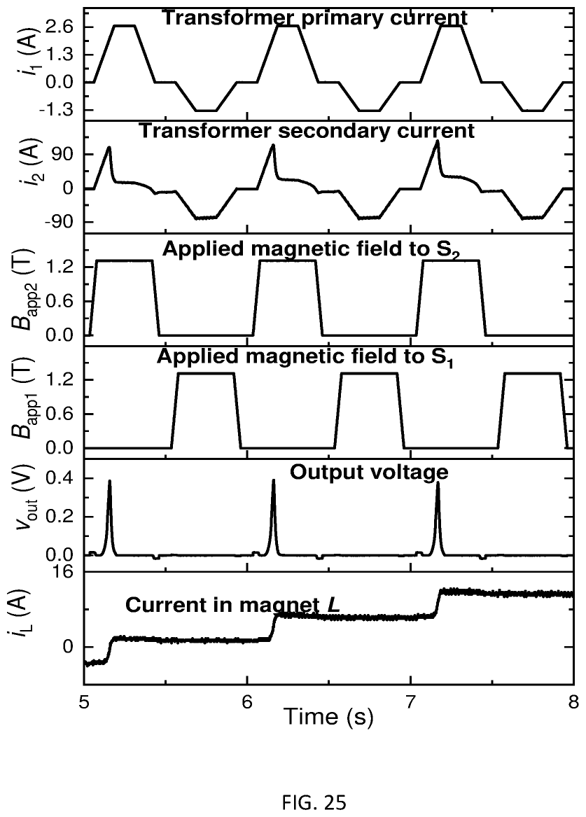

FIG. 25 illustrates measured magnitudes of the alternating input current i₁ in the primary coil 520 of the transformer 510, alternating current i₂ in the secondary coil 530 of the transformer 510, magnetic field Bₐₚₚ₂ generated by magnetic field generator 310b, magnetic field Bₐₚₚ₁ generated by magnetic field generator 310a, output voltage across the load 600 and current in the load 600 varying with time during use of the exemplary half-wave rectifier 100 of FIGS. 23 and 24 according to one form of the technology. The magnitude of the alternating input current i₁ may be controlled by the current supply assembly 500 (not shown) to have the illustrated wave-profile, i.e. extended periods of constant voltage at the current peaks, extended periods of dead-time at the zero crossings at which the alternating input current i₁ is zero and constant gradient transitions between the current levels. The control mechanism 400 may be configured to control the magnetic field generator 310b to apply a constant, non-zero magnetic field to electrical switch 210b when current i₁ is positive and a zero magnetic field when current i₁ is negative. The control mechanism 400 may be further configured to control the magnetic field generator 310a to apply a constant, non-zero magnetic field to electrical switch 210a when current i₁ is negative and a zero magnetic field when current i₁ is positive, i.e. in anti-phase to the activation/de-activation of magnetic field generator 310b. With these inputs, the output voltage across load 600 may be as illustrated in FIG. 25, i.e. with a non-zero voltage across the load 600 when the alternating current i₂ in the secondary coil 530 exceeds the critical current. If the load 600 comprises a length of superconducting material maintained in its superconducting state (e.g. in a cryostat below its critical temperature), the current in the load 600 may increase in step-like fashion (which may be described as “pumping”) for each pulse of output voltage across the load 600, as shown in FIG. 25.

In a similar way as explained in relation to a different form of the technology above, the control mechanism 400 may control both switch 210a and switch 210b to be simultaneously in the low-resistance state for some period of time in the alternating current cycle to ensure that a switch is in the open configuration (i.e. the higher-resistance state) when the current through it is in the desired direction.

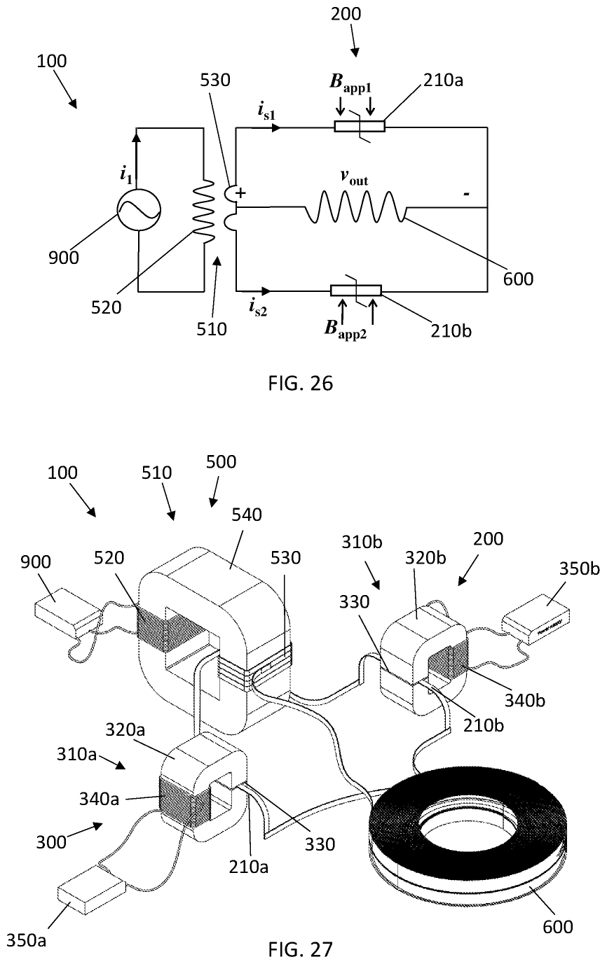

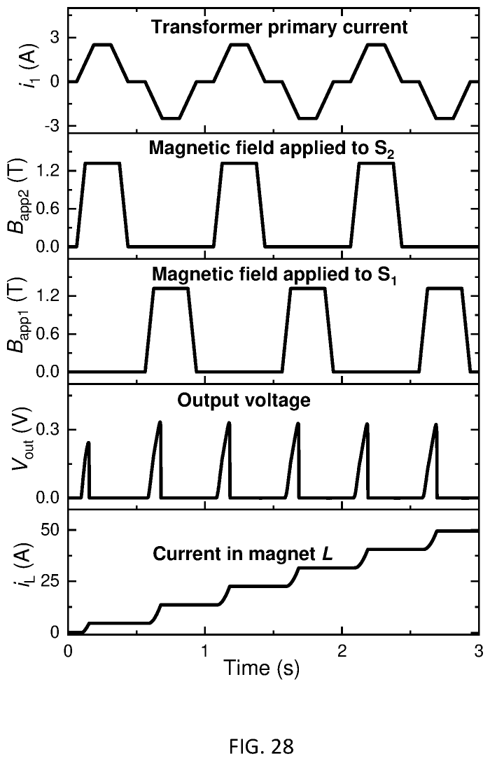

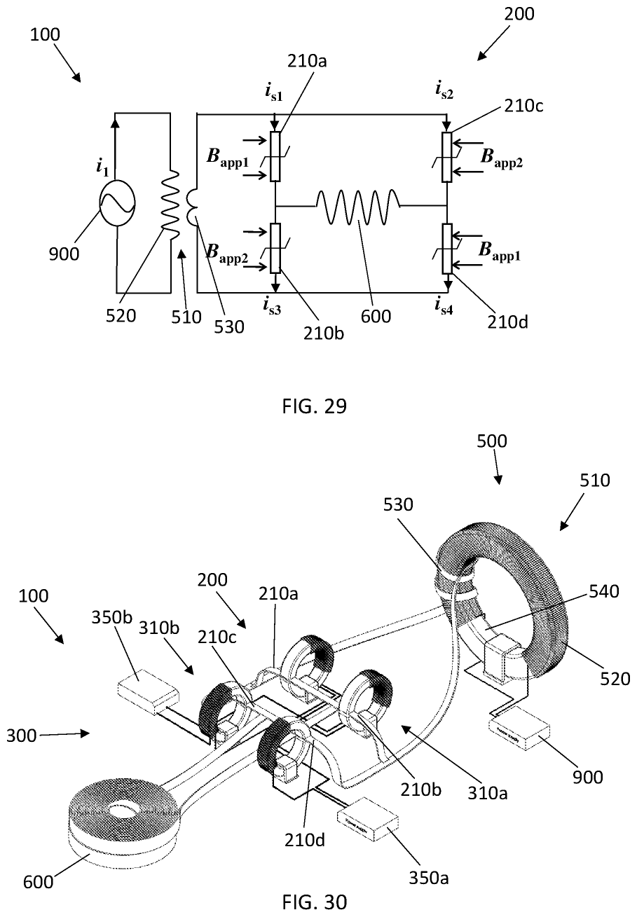

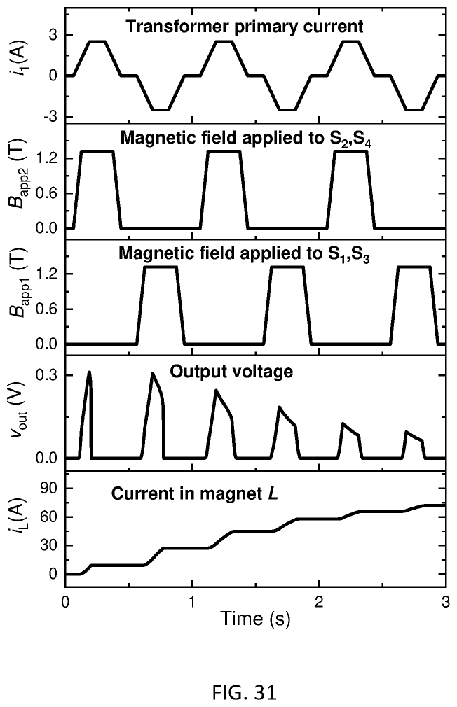

FIGS. 28 and 31 illustrate exemplary magnitudes of the same variables as shown in FIG. 25 (except the alternating current i₂ in the secondary coil 530 of the transformer 510) during simulated use of the exemplary full-wave rectifiers 100 of FIGS. 26 and 27 (in the case of FIG. 28) and FIGS. 29 and 30 (in the case of FIG. 31) according to certain forms of the technology. The effect of the exemplary full-wave rectifiers 100 is similar to that described above in relation to the half-wave rectifier of FIGS. 23 and 24, only a non-zero voltage is generated across the load 600 at two stages in the cycle, i.e. when the alternating current i₂ in the secondary coil 530 exceeds the critical current. Consequently the current in superconducting load 600 is pumped twice per cycle. Again the control mechanism 400 may control the two sets of switches to be simultaneously in the low-resistance state for some period of time in the alternating current cycle to ensure that a switch is in the open configuration (i.e. the higher-resistance state) when the current through it is in the desired direction.

Compared to the rectifiers shown in the earlier figures, the rectifiers 100 shown in FIGS. 23, 24, 26, 27, 29 and 30 may be able to operate more efficiently because the timing of switching of the switches may be able to be controlled to increase efficiency. This may enable the rectifier to operate with a lower cryogenic load to cool the superconducting materials and/or to increase the output power. The timing of the switching may also be able to be controlled to achieve other objectives. On the other hand, additional power supplies are needed, and the control mechanism is more complex, which may increase the cost and lead to a larger physical size compared to the earlier described rectifiers.

### 6.9. Current Supply Assembly

Rectifiers 100 according to certain forms of the technology comprise a current supply assembly 500 configured to supply alternating current to the lengths of HTS material in the switching assembly 200. The current supply assembly 500 may comprise an alternating current source 900. Alternatively or additionally, the current supply assembly 500 may receive a supply of alternating current from an external current source.

In the forms of the technology illustrated in FIGS. 3, 4, 5, 6, 8, 9, 10, 11, 12 and 13, the rectifiers 100 comprise a current control mechanism configured to control the alternating current flowing through the lengths of HTS material in the one or more electrical switches 210 (i.e. the alternating switch current) such that, in each cycle of current, there is a first peak of the current when the current flows in one direction (e.g. a positive direction) and a second peak of the current when the current flows in the other, opposite, direction (e.g. a negative direction) and where the magnitude of the current at the first peak is greater than the magnitude of the current at the second peak. In other words, the alternating switch current is controlled to be asymmetric through its cycle. Furthermore, the current control mechanism is configured so that the magnitude of the current at the first peak is greater than the critical current I_{c} of the length of the HTS material in the electrical switch 210 when the magnitude of the magnetic field applied by the magnetic field generator 310 is relatively high and the magnitude of the current at the second peak is less than the critical current I_{c} of the length of the HTS material in the electrical switch 210 when the magnitude of the magnetic field applied by the magnetic field generator 310 is relatively low.

In certain forms of the technology, the current supply assembly 500 (represented in the figures by alternating current source 900 but, as explained above, in other forms the current supply assembly 500 does not comprise a current source) comprises the current control mechanism and is configured to control the alternating input current i₁ so that the alternating current flowing through the switches 210 is asymmetric as described above. In other forms of the technology, the current supply assembly 500 may supply a symmetric alternating input current i₁ and the current control mechanism receives the symmetric alternating input current i₁ and provides the described asymmetric current to the switches 210.

FIG. 4A is an illustration of three graphs relating to the form of rectifier 100 shown in FIGS. 3 and 4:
1) the variation of the alternating input current i₁ and the variation of the magnetic field Bₐₚₚ applied by magnetic field generator 310 to the length of HTS material in switch 210 with time;
2) how the critical current I_{c} of the length of the HTS material in the electrical switch 210 varies with the magnetic field Bₐₚₚ applied by magnetic field generator 310 to the length of HTS material in switch 210; and
3) the variation of the voltage across the load 600 with time when the alternating input current i₁ is supplied.

During the current cycle, as the current through the magnetic field generator 310 (and also the current through the switch 210) increases, so does the magnitude of the magnetic field Bₐₚₚ applied to the switch 210. The increase in the magnetic field causes the critical current I_{c} of the length of the HTS material in the electrical switch 210 to decrease. The electrical switch 210 is put into the higher-resistance state when the switch current exceeds the critical current I_{c} of the length of the HTS material in the electrical switch 210. The current in the electrical switch equal to the critical current I_{c} is indicated as iₜₕ in FIG. 4A. Therefore, the voltage across the load 600 is non-zero when the current in the switch exceeds iₜₕ, and in the example of FIG. 4A this occurs in the positive part of the cycle because the alternating input current i₁ is controlled so that the positive peak exceeds the critical current iₜₕ. In FIG. 4A, this current is shown as the alternating input current i₁ since all the input current is assumed to flow through the electrical switch 210 when the switch is ‘closed’, i.e. in the low-resistance state.

When the current is below iₜₕ, the length of HTS material is in the low-resistance state so no current flows through the load 600. Furthermore, since the alternating input current i₁ is controlled so that the negative peak does not exceed the critical current iₜₕ (in magnitude), for all of the negative part of the cycle the length of HTS material remains in the low-resistance state, meaning negligible current flows through load 600. When repeated over multiple cycles a periodic positive voltage is produced across load 600, thereby half-wave rectifying the alternating input current i₁.

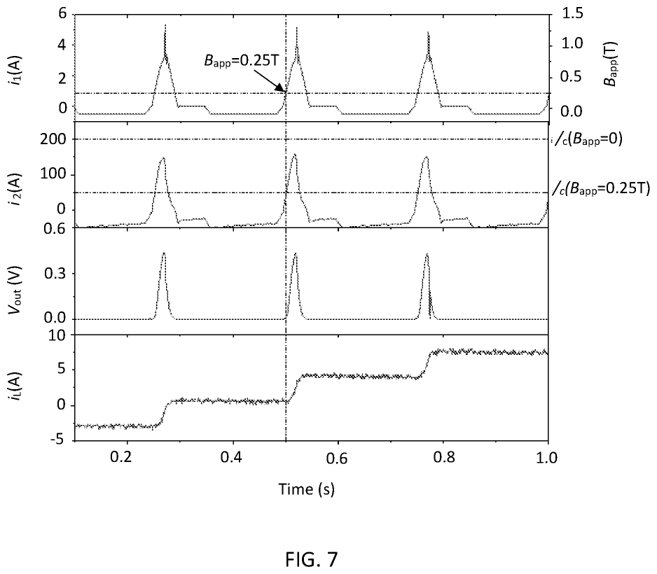

FIG. 7 is an illustration of four graphs showing the magnitudes of the following parameters varying with time during use of the rectifier 100 shown in FIGS. 5 and 6:
1) the alternating input current i₁ supplied to magnetic field generator 310 and to the primary coil 520 of transformer 510;
2) the alternating current i₂ generated in the secondary coil 530 of transformer 510;
3) the voltage across the load 600; and
4) the current in the load 600 (where the load 600 comprises a length of superconducting material maintained in its superconducting state, e.g. in a cryostat below its critical temperature).

In this example, the critical current I_{c} of the length of the HTS material in the electrical switch 210 in the absence of an externally applied magnetic field is 200 A. The alternating current i₂ carried by the electrical switch 210 does not exceed 200 A at any point in its cycle so is not sufficient to put the switch 210 into the higher-resistance state. With the application of a magnetic field of 0.25 T generated by magnetic field generator 310, the critical current I_{c} of the length of the HTS material in the electrical switch 210 decreases to approximately 50 A. In this case, once the alternating current i₂ carried by the electrical switch 210 exceeds 50 A, the switch 210 is switched into a higher-resistance state and a voltage is generated across load 600. Since the alternating input current i₁, and hence the alternating current i₂, is asymmetric, the switch 210 is only switched into the higher-resistance state during a positive part of the current cycle and the current is half-wave rectified. This results in a pumping of the current flowing in the load 600.

One advantage of the rectifiers 100 of the form of technology shown in FIGS. 3-6 is that the currents required for switching the switches 210 of the rectifier are significantly lower than those that would be required in the absence of an external magnetic field applied to the switches 210. This reduces the input current demand and reduces losses in the rectifier 100, increasing efficiency when generating the same level of current and voltage in the load 600. In the case of the parameters shown in FIG. 7, for example, the loss reduction is 75%.

As described above, in certain forms of the technology, the current control mechanism is configured to control the alternating current flowing through the one or more electrical switches 210 to be asymmetric and have the necessary peak magnitudes with respect to the critical current of the length of HTS material. The current control mechanism may achieve this control of the current in any suitable way. In certain forms the current control mechanism may comprise a programmable signal generator in which a digital signal representative of the desired waveform is provided to a digital-to-analog converter to generate an analog voltage signal with the appropriate asymmetric waveform. This analog voltage signal may be provided to a power amplifier to generate an asymmetric alternating input current.

In certain forms of the technology the current supply assembly 500 may comprise a transformer 510, as has already been described for many examples. The transformer may comprise a primary coil 520 connected to the current source 900 and a secondary coil 530 connected to the switching assembly 200. The transformer 510 may comprise a magnetic core 540 on which the primary coil 520 and secondary coil 530 are wound. In the rectifiers 100 of FIGS. 23, 24, 26, 27, 29 and 30, the alternating input current i₁ is supplied to the primary coil 520 of transformer 510 and the secondary coil 530 is connected to the switching assembly 200. In the rectifiers 100 of FIGS. 5, 6, 12, 14, 16, 17, 19, 20, 21 and 22 the magnetic field generator(s) 310 (specifically the conductor forming coil 340) is connected to the primary coil 520 of the transformer 510. In the rectifiers 100 of FIGS. 8, 9 and 13 the magnetic field generator(s) 310 (specifically the conductor forming coil 340) is connected to the secondary coil 530 of the transformer 510. In the rectifiers 100 of FIGS. 10 and 11, the transformer 510 and magnetic field generator 310 are comprised of the same components, as described in more detail above. In certain forms, the primary coil 520 may be formed from a normal conductor material and the secondary coil 530 may be formed from a superconducting material, for example a HTS material.

The rectifiers 100 comprising transformers 510 according to certain forms of the technology may be suitable for use in various applications, including superconducting magnets, superconducting motors/generators, space propulsion systems, fusion reactors, research magnets, NMR, MRI, levitation, water purification and induction heating, for example. The use of a transformer 510 in a rectifier enables two parts of the rectifier to be physically separated, meaning that such rectifiers can be used as, or in, flux pumps. The suitable form of rectifier for the application will depend on a variety of factors including physical size constraints, cryogenic heat loads, output power, efficiency, cost and controllability. In certain forms, the rectifiers 100 of FIGS. 5, 6, 8, 9, 10, 11, 12 and 13 may be considered suitable for compact, simple and/or low cost applications where requirements on factors such as efficiency, cryogenic heat load and output power may not be particularly demanding, for example some superconducting motor/generator or laboratory superconducting power supply applications. In certain forms, the rectifiers 100 of FIGS. 23, 24, 26, 27, 29 and 30 may be considered suitable for applications requiring high efficiency, low cryogenic heat loads and/or high power output, for example space propulsion or fast ramping large magnets. The rectifiers of other figures may be suitable for other applications, for example.

### 6.10. Thermal Breaks

The electrical switches 210 and rectifiers 100 in certain forms of technology comprise components made of superconducting materials, for example HTS materials. The superconducting materials must be maintained in an environment having a temperature that is less than the critical temperature of the superconducting material for the superconducting material to adopt the low-resistance (“superconducting”) state. Rectifiers 100 according to forms of the technology may comprise a cryostat 700 configured to maintain the rectifier 100, or parts thereof, in a suitably cold environment with a temperature less than the critical temperature of one or more of the superconducting materials in the rectifier 100.

It may be costly in energy terms to maintain certain parts of the rectifier 100 at low temperatures in a cryostat 700 if this is not needed for the operation of the rectifier 100. However, maintaining some parts of a rectifier 100 at a low temperature while others are maintained at a warmer temperature may result in heat losses from the cryostat 700, increasing energy cost. Consequently certain forms of the technology comprise one or more thermal breaks 710 to thermally insulate one or more parts of the rectifier 100 from one or more other parts of the rectifier 100 in order to reduce the flow of thermal energy where it is desirable to maintain different parts at different temperatures.

Forms of the technology are not limited by the form or configuration of the thermal breaks 710. In certain forms a thermal break 710 comprises one or more elements formed of thermally insulating material. Additionally, or alternatively, a thermal break 710 may comprise regions of vacuum. Additionally, or alternatively, a thermal break 710 may comprise one or more radiation shields.

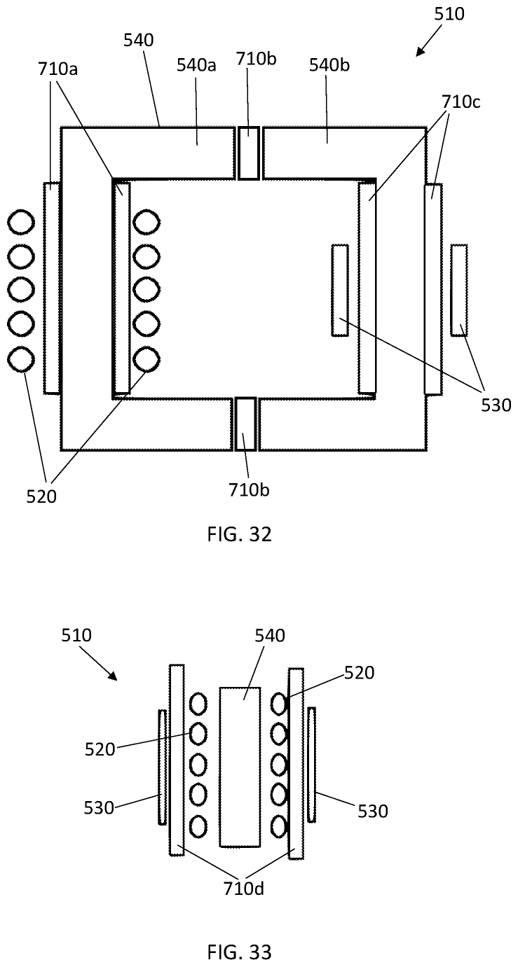

FIG. 32 is a schematic illustration of a transformer 510 according to certain forms of the technology. The transformer 510 may comprise any one or more of the following different types of thermal break 710:
1) A thermal break 710a may be positioned between the primary coil 520 and the magnetic core 540;
2) A thermal break 710b may be positioned between a first part of the magnetic core 540a and a second part of the magnetic core 540b. In certain forms, the primary coil 520 may be wound around the first core part 540a and the secondary coil 530 may be wound around the second core part 540b; and
3) A thermal break 710c may be positioned between the secondary coil 530 and the magnetic core 540.

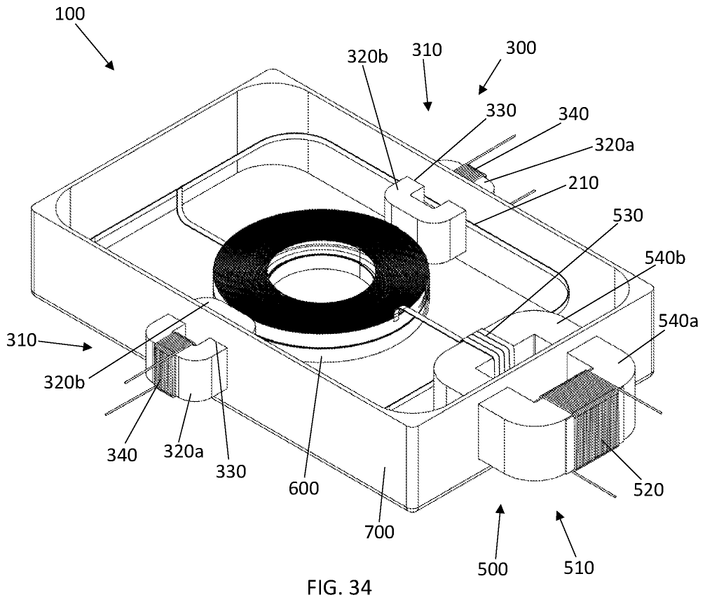

FIG. 33 is a schematic illustration of a transformer 510 according to certain forms of the technology in which the transformer 510 has a co-axial geometry and the primary coil 520 and the secondary coil 530 are co-wound, with one of the coils being wound closer to the axis than the other coil. Such a transformer 510 may comprise a thermal break 710d between the primary coil 520 and the secondary coil 530.

Similarly, any one or more of the magnetic field generators 310 of the rectifier 100 may comprise one or more thermal breaks 710, for example: a thermal break between a first part of the magnetic core 320a and a second part of the magnetic core 320b; and a thermal break between the magnetic core 320 and the coil 340 of conductor wound around the magnetic core 320.

Forms of the technology envisage that rectifiers 100 may be configured to include thermal breaks 710 at any number of locations where necessary to provide thermal insulation between a ‘cold’ environment to enable superconducting behaviour and a ‘warm’ environment.

One example of a rectifier 100 comprising thermal breaks 710 is illustrated in FIG. 34. In FIG. 34, the magnetic cores of each of a transformer 510 and first and second magnetic field generators 310 are split into two core parts, with each magnetic core having one of the core parts located inside a cryostat 700 and the other core part located outside the cryostat 700. The two parts of each magnetic core are magnetically coupled together. The inside of the cryostat 700 is maintained at a temperature sufficiently low to enable the lengths of the superconducting material positioned inside the cryostat 700, including those forming electrical switches 210, to operate in the low-resistance, or superconducting, state. The walls of the cryostat 700 therefore form the thermal breaks 710. The layout of the rectifier 100 in FIG. 34 is otherwise similar to that of the rectifier 100 shown in FIGS. 26 and 27.

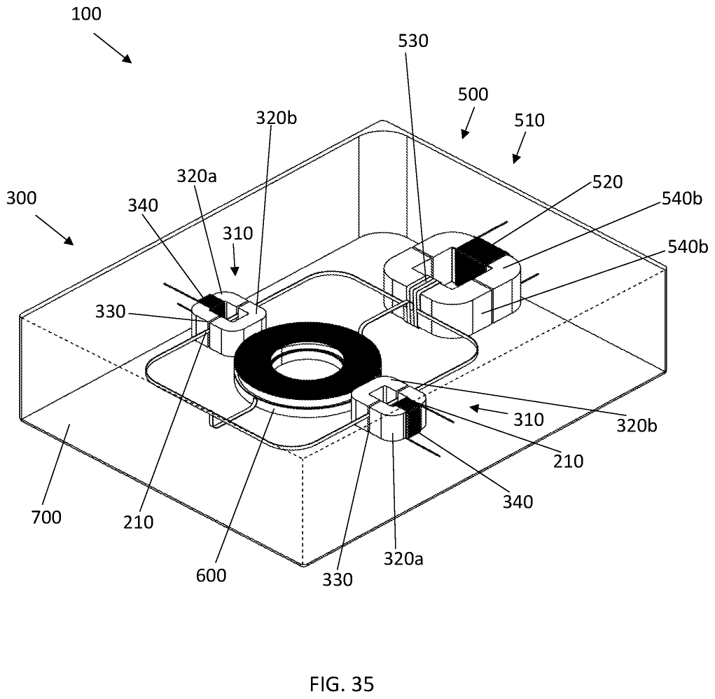

Another example of a rectifier 100 comprising thermal breaks 710 is illustrated in FIG. 35. This form again illustrated a rectifier 100 having a layout similar to that of the rectifier 100 shown in FIGS. 26 and 27. In this form, all of the magnetic cores 320 and 540 of the magnetic field generators 310 and the transformer 510 are located inside the cryostat 700. The magnetic cores of each of the transformer 510 and first and second magnetic field generators 310 and 310 are split into two core parts, with the two core parts in each magnetic core being separated by a thermal break 710. The two parts of each magnetic core are magnetically coupled together. Conductors connecting to the primary coil 520 of the transformer and to the coils 340 of the magnetic field generators 310 pass through the walls of the cryostat 700.

### 6.11. Bifilar Arrangement

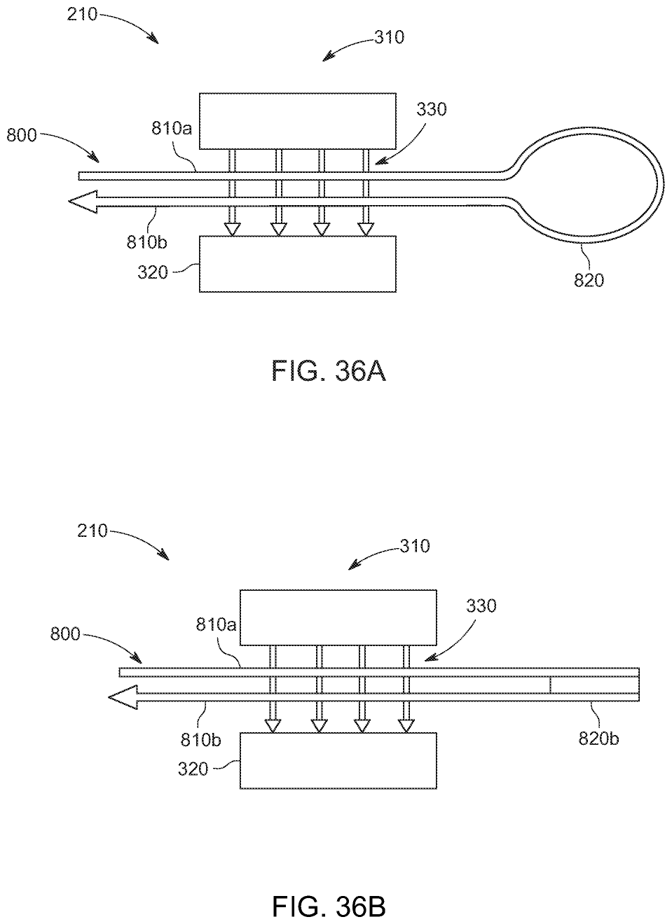

Forms of the technology have been described that relate to electrical switches 210 that utilise the principle that the critical current of a superconducting material decreases as a higher external magnetic field is applied to the material. One exemplary electrical switch 210a is illustrated in FIG. 24. The electrical switch 210a in FIG. 24 comprises a length of superconducting material arranged in a bifilar arrangement. Another electrical switch 210 comprising a length of superconducting material arranged in a bifilar arrangement is shown in FIG. 36. This aspect of the technology will now be described in more detail.

It should be understood that, while a bifilar arrangement of the length of superconducting material is described in relation to the forms of electrical switch 210 shown in FIGS. 24, 36A and 36B, the bifilar arrangement may also be applied to other forms of the technology. In particular, any of the electrical switches 210 described in this specification may, in alternative forms of the technology, comprise a length of superconducting material arranged in a bifilar arrangement. Furthermore, any electrical switch 210 incorporated into any rectifier 100 according to forms of the technology may comprise a length of superconducting material arranged in a bifilar arrangement.

In the context of this specification, unless otherwise stated, a “bifilar arrangement” should be understood to mean an arrangement of two strands of a conductor in which the two strands of the conductor are substantially parallel and electrically connected so that current flows through the strands in opposite directions. The strands may be closely adjacent to each other. The strands may be two sections of a length of superconducting material that is doubled back on itself. Alternatively, the two strands may be separate lengths of superconducting material that are electrically connected together, for example by soldering, diffusion joint or other suitable form of electrical connection.

It should also be understood that, in certain forms of the technology, multiple bifilar strands may be used. Therefore, unless the context clearly requires otherwise, where a bifilar arrangement is described, other forms of the technology may include a similar arrangement with multiple bifilar strands.

More particularly, for example referring to the form of the technology illustrated in FIG. 36A, in one form of bifilar arrangement, an electrical switch 210 comprises a length 800 of superconducting material. The length 800 of superconducting material comprises two strands (i.e. sub-lengths) 810a and 810b of superconducting material. The two strands 810a and 810b are connected in series to each other. The length 800 of superconducting material is arranged so that it doubles back on itself and the two strands 810a and 810b are spatially arranged substantially parallel to each other. In this arrangement, when the length 800 of superconducting material is carrying a transport current, the current in the first strand 810a flows in the opposite direction to the current in the second strand 810b. A fold region 820 (which may take the form of a loop) of the length 800 of superconducting material may separate the two strands 810a and 801b along the length of the length 800 of superconducting material.

In the alternative form of the technology shown in FIG. 36B, electrical switch 210 comprises two separate strands 810a and 810b of superconducting material. One end of each of the two strands 810a and 810b are electrically connected together at electrical connection 820b and the two strands are in a bifilar arrangement. Again, in this arrangement, when the length 800 of superconducting material is carrying a transport current, the current in the first strand 810a flows in the opposite direction to the current in the second strand 810b. The electrical connection 820b may be a solder joint, a diffusion joint, or any suitable electrical joint.

In the forms of the technology shown in FIGS. 36A and 36B, the two strands 810a and 810b may also be arranged closely adjacent to each other. An insulation coating may be applied to one or both of the strands 810a and 810b and the insulating coatings of the strands may be in contact with each other. Alternatively, an insulating layer may be placed between the two strands 810a and 810b in contact with one or both strands. The insulating layer may be formed of an insulating tape, for example Kapton or Nomex tape.

In certain forms of the technology, the length 800 of superconducting material may take the form of a tape, i.e. a length of material having a length that is significantly larger than its width and its depth, and a width that is significantly larger than its depth. The tape may have two substantially parallel opposed faces, where the faces are separated by the depth of the tape. The strands may be arranged so that the opposed faces of one strand 810a are parallel with the opposed faces of the other strand 810b. In the form of the technology shown in FIG. 36B, each of the two strands 810a and 810b may take the form of a tape. The two separate strands may be electrically connected (e.g. soldered) face-to-face at one end to form an electrically continuous joint 820b. This arrangement may reduce the inductance of electrical switch 210, although this benefit may be achieved at the expense of a small increase in the resistance of the low-resistance state. Alternatively, a single length of superconducting material (e.g. tape) may be arranged with the two strands 10a and 810b as adjacent sections of the length joined end-to-end.

In certain forms of the technology, the length 800 of superconducting material may be a length of high temperature superconducting (HTS) material, as explained earlier.

As shown in the forms of the technology in FIGS. 24, 36A and 36B, an electrical switch 210 of certain forms of the technology may be arranged such that a magnetic field generator 310 is able to be activated to apply a magnetic field to the two strands 810a and 801b of superconducting material. The magnetic field generator 310 may take the form of any of the magnetic field generators described earlier in this specification. The magnetic field generator 310 may be selectively controlled to selectively generate a magnetic field in order to cause the electrical switch 210 to move between a low-resistance state and a higher-resistance state in the manner explained earlier.

In certain forms, the magnetic field generator 310 comprises a magnetic core 320. The core 320 may be a high-permeability magnetic core such as a ferromagnetic core, for example a ferrite core (e.g. an iron core) or a laminated steel/iron core. In the exemplary form shown in FIG. 24, the magnetic core 320a is a substantially ring-shaped solid core, for example a circular ring. In other forms, the core may have a different shape, for example a square-shaped ring having rounded corners. In the exemplary forms, the magnetic core 320 comprises first and second ends separated by a gap 330. The gap 330 may be a space in a solid magnetic core 320, for example a space in one side of a ring core.

In certain forms, the electrical switch 210 is arranged so that the magnetic field generated by the magnetic field generator 310 is substantially perpendicular to the opposed faces of the strands 810a and 801b. That is, the lines of magnetic flux of the magnetic field are substantially perpendicular to the faces of the strands 810a and 801b where the lines of flux intersect the strands.

In certain forms of the technology, the width of the gap 330 is similar to the combined depth of the two strands 810a and 810b, i.e. there is relatively little air gap separating each of the strands 810a and 810b from the respective end of the core 330 nearest to the strand.

One benefit of an electrical switch 210 comprising a bifilar arrangement of a length of superconducting material is that the inductance of the switch is reduced compared to a similar switch with a single length of superconducting material. One practical advantage of this may be that a coil 340 of the magnetic field generator 310 applying a magnetic field to the electrical switch 210 may have fewer turns than would otherwise need to be the case.

Another benefit of an electrical switch 210 comprising a bifilar arrangement of a length of superconducting material is that it assists in reducing suppression of the critical current of the length of superconducting material when the magnetic field applied to the length of superconducting material is low, for example zero. This leads to a higher critical current for the low-resistance state of the switch 210. This effect will now be explained in more detail.

Forms of the technology described above comprise electrical switches 210 in which a magnetic field is applied to a length of superconducting material in order to suppress the critical current in the length of superconducting material. This effect is used in some forms of the technology to transition the length of superconducting material between a low-resistance state and a higher-resistance state. The magnetic field generator 310 that generates the magnetic field may comprise a high-permeability core 320, for example a ferromagnetic core, which may be used to focus the magnetic field onto the length of superconducting material.

It has been observed that, when a single length of superconducting material carrying a transport current is placed proximate a ferromagnetic core, there is additional suppression of the critical current, even when the strength of the magnetic field is low, including zero. In fact, the relative additional suppression of the critical current as a result of this effect is greater when the applied magnetic field strength is lower. This is due to a self-field magnification effect caused by the proximity of ferromagnetic material in the core 320 to the superconducting material when current is flowing. More particularly, it has been identified, through experimentation and finite element analysis, that the presence of a low-reluctance return path through the ferromagnetic core 320 causes the self-field of a unifilar length of superconducting material to be amplified and, where the unifilar length of superconducting material is in the form of a tape, to be oriented perpendicular to the tape and to be spread across its width. This causes suppression of the critical current density of each point across the width of the tape, and hence suppression of the total critical current compared to when no ferromagnetic core is present.

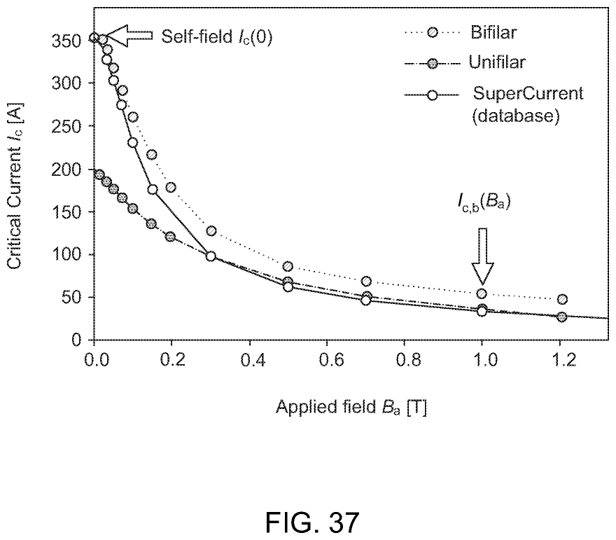

It has further been identified that an electrical switch 210 in which the length of superconducting material is arranged in a bifilar arrangement significantly mitigates against this effect, i.e. it reduces the described suppression of the critical current. Put another way, the bifilar arrangement substantially cancels the self-magnetic field generated by the current flowing through the length of superconducting material when in proximity to the ferromagnetic core 320. FIG. 37 illustrates the critical current of a length of superconducting material in an electrical switch 210 according to a form of the technology at different applied fields and when the length of superconducting material is arranged in a bifilar arrangement (blue, top line) and a unifilar arrangement (orange, bottom line), i.e. a single layer of a length of superconducting material. These experimental results are compared to reference values for the superconducting material from a database (green, dashed, middle line). This illustrates that the suppression of the critical current at low applied fields is very low for the bifilar arrangement compared to the unifilar arrangement. The difference is less significant at higher applied fields where the applied magnetic field is significantly larger than any self-field effects. The relatively small difference in the critical current at higher applied fields may be due to an increase in the shielding capability of the two-layer bifilar arrangement compared to the single layer unifilar arrangement. It should be appreciated that the length of superconducting material may be maintained in a superconducting state at all times in certain forms of the technology.

A greater difference between the critical current for low applied magnetic fields compared to high applied magnetic fields means that an electrical switch 210 comprising a length of superconducting material in a bifilar arrangement may have an improved switching performance compared to, for example, a switch with a unifilar arrangement. The switching performance may be given by a switching factor κ, which may calculated as the ratio of the critical current when the magnetic field is zero to the critical current when the magnetic field is applied, i.e. I_{c}(0)/I_{c,b}(Bₐ). It can be seen from FIG. 37 that κ is greater for the bifilar arrangement than the unifilar arrangement. A higher switching factor κ means a more efficient switch, as long as the transport current is lower than I_{c}(0). Also, a higher critical current in the low resistance state enables the electrical switch 210 to output a higher maximum current.

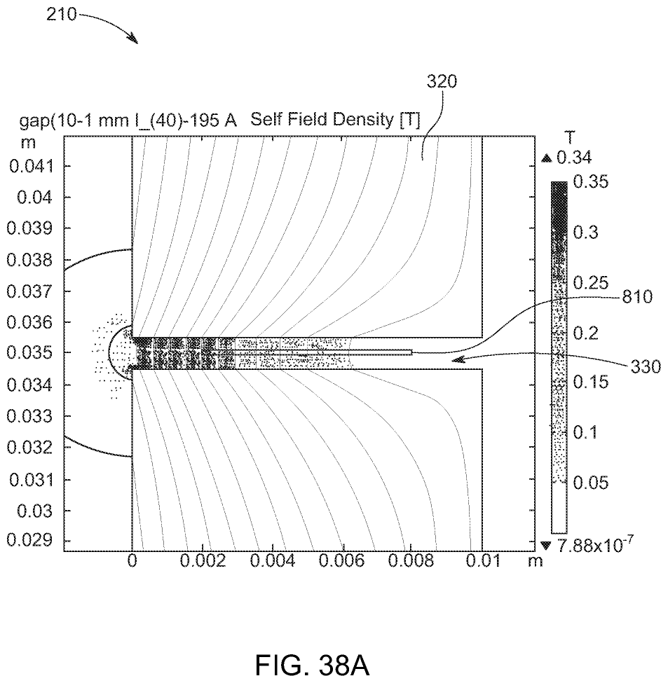

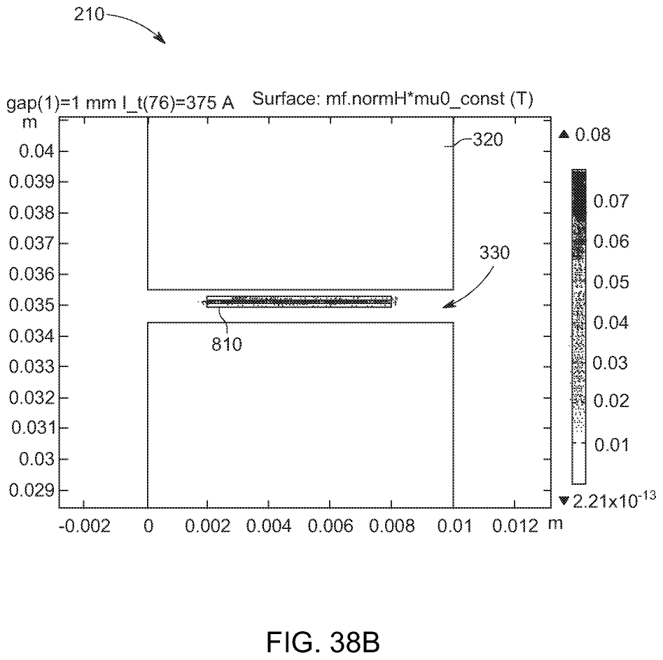

FIGS. 38A and 38B show magnetic field profiles within the gap between the ends of the ferromagnetic core 320 for electrical switches 210 according to certain forms of the technology. The electrical switch 210 comprises a length 810 of superconducting material in the form of a tape positioned between two ends of a ferromagnetic core 320. The magnetic field profiles are generated by finite element analysis. In FIG. 38A the tape is arranged in the gap 330 between the ends of the core 320 in a unifilar arrangement, i.e. a single length of tape passes through the gap 330. In FIG. 38A, the tape is modelled as carrying a current of 195 A and the magnetic field applied to the tape is modelled as having a magnetic field strength of 250 mT. In FIG. 38B the tape is arranged in the gap 330 between the ends of the core 320 in a bifilar arrangement, i.e. two strands of the tape are arranged in the gap 330 parallel to each other and closely adjacent. In FIG. 38B, the tape is modelled as carrying a current of 375 A and the magnetic field applied to the tape is modelled as having a magnetic field strength of 70 mT.

FIGS. 38A and 38B show that the average magnetic field magnitude in the form of the technology in which the length of superconducting material is arranged in a unifilar arrangement (FIG. 38A) is significantly greater than that in the form of the technology in which the length of superconducting material is arranged in a bifilar arrangement (FIG. 38B). In fact, the bifilar arrangement almost eliminates the tape's self-inductance and the remaining magnetic field on the tape is largely in a direction parallel to the face of the tape. This explains why the critical current of the bifilar arrangement at zero applied field is significantly larger than for the unifilar tape (as shown in FIG. 37).

It has also been identified that, the larger the gap 330 between the ends of the core 320, the lower the magnetic field strength of the applied field. This means that, if the gap 330 is increased, a larger current supply may be needed to be supplied to the magnetic field generator in order to maintain the same magnetic field strength. This may be undesirable as it requires additional driving power and dissipates additional heat. Consequently, in certain forms of the technology, the size of the gap 330 may be as small as practically possible, for example the width of the gap 330 is similar to the combined depth of the two strands of the length 810 of superconducting material.

### 6.12. Other Remarks

Unless the context clearly requires otherwise, throughout the description and the claims, the words “comprise”, “comprising”, and the like, are to be construed in an inclusive sense as opposed to an exclusive or exhaustive sense, that is to say, in the sense of “including, but not limited to”.

The entire disclosures of all applications, patents and publications cited above and below, if any, are herein incorporated by reference.

Reference to any prior art in this specification is not, and should not be taken as, an acknowledgement or any form of suggestion that that prior art forms part of the common general knowledge in the field of endeavour in any country in the world.

The technology may also be said broadly to consist in the parts, elements and features referred to or indicated in the specification of the application, individually or collectively, in any or all combinations of two or more of said parts, elements or features.

Where in the foregoing description reference has been made to integers or components having known equivalents thereof, those integers are herein incorporated as if individually set forth.

It should be noted that various changes and modifications to the presently preferred embodiments described herein will be apparent to those skilled in the art. Such changes and modifications may be made without departing from the spirit and scope of the technology and without diminishing its attendant advantages. It is therefore intended that such changes and modifications be included within the present technology.

1. An electrical switch comprising:
first and second strands of superconducting material, each of the first and second strands of superconducting material being configured to carry a transport current and having a critical current; and
a magnetic field generator configured and arranged to apply a magnetic field to the first and second strands of superconducting material, wherein the magnetic field generator comprises a high permeability magnetic core,
wherein the magnetic field generator is configured to be selectively controlled to switch the electrical switch between a low-resistance state when a magnitude of the magnetic field is relatively low and a higher-resistance state when a magnitude of the magnetic field is relatively high, wherein in the low-resistance state the transport current is substantially less than the critical current, and in the higher-resistance state the transport current approaches the critical current, is substantially equal to the critical current or is greater than the critical current, and
wherein the first and second strands of superconducting material are spatially arranged substantially parallel to each other within a region of the magnetic field and are electrically connected so that the transport current flows in opposite directions through the first and second strands of superconducting material within the region of the magnetic field.

2. The electrical switch as claimed in claim 1, wherein the high permeability magnetic core comprises a first end and a second end separated by a gap, the first and second strands of superconducting material being positioned in the gap.

3. The electrical switch as claimed in claim 1, wherein the first and second strands of superconducting material are in the form of tapes each having two opposed faces.

4. The electrical switch as claimed in claim 3, wherein the tapes are arranged so that the opposed faces of the first strand of superconducting material are parallel with the opposed faces of the second strand of superconducting material.

5. The electrical switch as claimed in claim 4, wherein the tapes are oriented such that the magnetic field applied to the first and second strands of superconducting material is substantially perpendicular to each of the two opposed faces.

6. The electrical switch as claimed in claim 1, wherein the electrical switch comprises a single length of superconducting material comprising the first and second strands of superconducting material integrally joined end-to-end.

7. The electrical switch as claimed in claim 1, wherein the first and second strands of superconducting material are electrically connected by connecting a face of the first strand to a face of the second strand.

8. The electrical switch as claimed in claim 1, wherein the superconducting material is high temperature superconducting (HTS) material.

9-36. (canceled)
